(19) United States
(12) Patent Application Publication
(10) Pub. No.: US 2013/0194016 A1
(43) Pub. Date: Aug. 1, 2013

(54) SYSTEM AND METHOD FOR GENERATING A CLOCK GATING NETWORK FOR LOGIC CIRCUITS

(71) Applicant: SHMUEL WIMER, (US)

(72) Inventor: SHMUEL WIMER, (US)

(21) Appl. No.: 13/361,986

(22) Filed: Jan. 31, 2012

(51) Int. Cl. H03K 3/00

(52) U.S. Cl. 327/199

(57) ABSTRACT

A system and method for generating a power efficient clock gating network for a Very Large Scale Integration (VLSI) circuit. Statistical analysis is performed upon the activity of component registers of the circuit and registers having correlated toggling behavior are clustered into sets and provided with common clock gaters. The clock gating network may be generated independently from the logical structure of the circuit.

### FIELD AND BACKGROUND OF THE INVENTION

The disclosure herein relates to Very Large Scale Integration (VLSI) circuit and system design. In particular the disclosure relates to statistically determined clock gating networks and their application to power efficient logic circuits and systems.

The increasing demand for low power mobile computing and consumer electronics products has refocused Very Large Scale Integration (VLSI) design in the last two decades on lowering power and increasing energy efficiency. In particular, power reduction is treated at all design levels of VLSI chips, from architecture through block and logic levels, down to gate-level, circuit and physical implementation.

One of the major dynamic power consumers is the system's clock signal, which may be responsible for up to 50% of the total dynamic power consumption or more. Clock network design is a delicate procedure, and may be therefore done in a very conservative manner under worst case assumptions. It incorporates many diverse aspects such as selection of sequential elements, controlling the clock skew, and decisions on the topology and physical implementation of the clock distribution network.

Several techniques to reduce the dynamic power have been developed, of which clock gating is predominant. When a logic unit is clocked, its underlying sequential elements generally receive clock signal regardless of whether or not they will toggle in the next cycle. With clock gating, the clock signals may be combined, for example using AND gates, with explicitly defined enabling signals. Clock gating may be employed at any level of the system, for example in the system architecture, block design, logic design, gates or the like.

Clock enabling signals are generally introduced during the system and block design phases, where the interdependencies of the various functions are established. In contrast, it may be more difficult to define such signals at the gate level, especially in control logic, since the interdependencies among the states of various flip-flops (FFs) may depend on automatically synthesized logic.

### SUMMARY OF THE INVENTION

Gating of the clock signal in integrated circuits such as Very Large Scale Integration (VLSI) generated chips may be a mainstream design methodology for reducing switching power consumption. A probabilistic model has been developed for the clock gating network that may enable the expected power savings to be quantified as well as the overhead implied thereby.

Expressions for the power savings in a gated clock tree are presented and a gater fan-out is derived, which is based on flip-flops toggling probabilities and process technology parameters. The resulting clock gating methodology may significantly reduce the total clock tree switching power significantly.

Possible configurations of flip-flops are presented for embodiments of a joint clocked gating. For illustrative purposes only, particular embodiments are presented relating to a graphics processor and a 16-bit microcontroller.

It has been surprisingly found that the power savings achievable through a knowledge of the toggling behavior of FFs in a system is significantly greater than the power savings of clock disabling derived from the Hardware Description Language (HDL) definitions. A knowledge of toggling behavior may be obtained through statistical analysis of FF activity of a logic circuit or system and how they are correlated with each other. This may be illustrated by comparing HDL-based gating with manual insertion of gating for a programmable interrupt controller (PIC). In some cases, where HDL-based gating may reduce clock power by perhaps 25%, while manual insertion of gating logic to every FF was surprisingly found to increase the power savings by up to 50% or more.

An efficient system and method for providing clock gating based upon actual flip-flop activity would therefore present a significant improvement over known clock disabling systems.

Accordingly, a method is taught herein for generating a clock gating network for a Very Large Scale Integration (VLSI) system or circuit. The method comprises: obtaining toggling probabilities of a plurality of flip-flops of the system or circuit; clustering sets of correlated flip-flops having correlated toggling behavior; and providing a common gater for each cluster of correlated flip-flops.

Optionally, toggling probabilities may be obtained by: obtaining a hardware description of a logic circuit or system; executing a simulation with a representative test bench of the logic circuit or system; and performing statistical analysis of toggling behavior of the plurality of flip-flops.

Where appropriate, the clustering may involve: determining a size k for each cluster; and selecting k flip-flops having correlated toggling behavior.

Additionally the method may include obtaining a preliminary layout of the flip flops by executing a placement algorithm. Accordingly, the clustering may comprise: selecting a set of correlated flip-flops from a common vicinity.

Furthermore, the method may include generating an updated hardware description by introducing the common gaters into the hardware description of the circuit. Accordingly, the method may additionally comprise verifying flip-flop outputs for the updated hardware description.

In various embodiments, the method may additionally, or alternatively, include: applying place and route tools; and executing clock-tree synthesis.

Optionally, the method may further comprise: executing a gate-level simulation of the logic circuit or system including the clusters of correlated flip-flops and the gaters; performing statistical analysis of the behavior of the gaters; clustering sets of correlated gaters; and providing a common higher level gater for each cluster of correlated low level gaters.

Another method is taught for generating a clock gating network for a logic circuit or system comprising a plurality of registers, the method may include: obtaining a hardware description of the logic circuit or system; executing a simulation with a representative test bench of the logic circuit or system; performing statistical analysis of behavior of the plurality of registers; clustering sets of statistically correlated registers; and providing a common gater for each cluster of correlated registers.

The disclosure herein further presents a clock gating network for a Very Large Scale Integration (VLSI) circuit, the network comprising a plurality of clusters of correlated registers the correlated registers having statistically correlated toggling behavior, wherein each cluster of correlated registers is gated by a common gater.

Optionally, the correlated registers are selected by obtaining a hardware description of a logic circuit or system, executing a gate-level simulation with a representative test bench of the logic circuit or system; and performing statistical analysis of toggling behavior of the plurality of registers.

The clock gating network may comprise a tree structure wherein at least one higher level gater is configured to drive a cluster of lower level gaters. Where appropriate, the size k of each cluster of registers, the number a′ of gating levels and the number n of wires in the circuit may be selected such that

$$\frac{d}{d t } {C}_{net saving}^{1 - {α}^{′}} = 0 ,$$

where Cₙₑₜ_{_{—}}_{saving}^{1-α′}=ncₙₑₜ_{_{—}}_{saving}¹+Σⱼ₌₂^{α′}(n/k^{j-1})cₙₑₜ_{_{—}}_{saving}^{j}.

It is noted that the correlated registers may variously comprise flip-flops. Additionally, or alternatively, the correlated registers comprise gated clusters of flip-flops.

It is noted that in order to implement the methods or systems of the disclosure, various tasks may be performed or completed manually, automatically, or combinations thereof. Moreover, according to selected instrumentation and equipment of particular embodiments of the methods or systems of the disclosure, some tasks may be implemented by hardware, software, firmware or combinations thereof using an operating system. For example, hardware may be implemented as a chip or a circuit such as an ASIC, integrated circuit or the like. As software, selected tasks according to embodiments of the disclosure may be implemented as a plurality of software instructions being executed by a computing device using any suitable operating system.

In various embodiments of the disclosure, one or more tasks as described herein may be performed by a data processor, such as a computing platform or distributed computing system for executing a plurality of instructions. Optionally, the data processor includes or accesses a volatile memory for storing instructions, data or the like. Additionally or alternatively, the data processor may access a non-volatile storage, for example, a magnetic hard-disk, flash-drive, removable media or the like, for storing instructions and/or data. Optionally, a network connection may additionally or alternatively be provided. User interface devices may be provided such as visual displays, audio output devices, tactile outputs and the like. Furthermore, as required user input devices may be provided such as keyboards, cameras, microphones, accelerometers, motion detectors or pointing devices such as mice, roller balls, touch pads, touch sensitive screens or the like.

### BRIEF DESCRIPTION OF THE DRAWINGS

For a better understanding of the embodiments and to show how it may be carried into effect, reference will now be made, purely by way of example, to the accompanying drawings.

With specific reference now to the drawings in detail, it is stressed that the particulars shown are by way of example and for purposes of illustrative discussion of selected embodiments only, and are presented in the cause of providing what is believed to be the most useful and readily understood description of the principles and conceptual aspects. In this regard, no attempt is made to show structural details in more detail than is necessary for a fundamental understanding; the description taken with the drawings making apparent to those skilled in the art how the several selected embodiments may be put into practice. In the accompanying drawings:

FIGS. 1A and 1B show an example of a clock enabling flip flop for use in embodiments of gating networks;

FIGS. 2A and 2B show a possible gate configuration which may be used to combine multiple clock enabling signals into a common gating signal;

FIG. 3 schematically illustrates an example of a flip flop to flip flop logic stage with its driving clock signals;

FIG. 4 represents the timing sequence for the logic stage of FIG. 3;

FIG. 5 represents a possible clock tree distribution network for joining enabling signals of individual flip flops;

FIG. 6 represents how clock drivers may be replaced with gaters in a clock tree;

FIG. 7 is a histogram representing the activity factors for a gate level test bench for a 16-bit microcontroller;

FIG. 8 is a histogram representing the activity factors for a gate level test bench for a rasterization unit used in a 3D graphics accelerator;

FIG. 9 is a graph showing the normalized power savings of obtained by adaptive gating at the first level of a clock tree compared to the non gated situation;

FIG. 10 is a graph showing the normalized power savings of obtained by adaptive gating at the lower three levels of a clock tree compared to the non gated situation;

FIG. 11 shows an activity correlation metrics for a 16-bit micro-controller;

FIG. 12 shows joint toggling correlation for the 16-bit micro-controller;

FIG. 13 shows an activity correlation metrics for a 3D graphics accelerator;

FIG. 14 shows joint toggling correlation for the 3D graphics accelerator;

FIG. 15 is a histogram representing the activity factors for an industrial DSP block comprising 22K flip flops over 240K clock cycles;

FIG. 16 is a histogram representing the activity factors for another control block of an industrial network processor comprising 37K flip flops over 6.3K clock cycles;

FIG. 17 shows activity similarity for the industrial DSP block comprising 22K flip flops over 240K clock cycles;

FIG. 18 shows activity similarity for control block of an industrial network processor comprising 37K flip flops over 6.3K clock cycles;

FIGS. 19A and 19B presents a counterexample to 4-size FF grouping by bottom-up Minimal Cost Perfect Graph Matching (MCPM);

FIG. 20 is a table representing the results of flip flop grouping for a 3D graphics accelerator;

FIG. 21A and 21B, show the distribution of the number of flip flops in a clock domain of a DSP block and a network processor control block respectively;

FIG. 22 is a histogram illustrating the negative slack distribution in a 3D graphics accelerator for 200 MHz clock cycle, with and without gating; and

FIG. 23 is a flowchart representing the main actions in a method for generating a clock gating network for a Very Large Scale Integration (VLSI).

### DETAILED DESCRIPTION OF THE INVENTION

Aspects of the present disclosure relate to the gating of Very Large Scale Integration (VLSI) circuits. In particular embodiments are presented for the generation of gating networks based upon the actual behavior of a logic circuit or systems' component registers, such as flip-flops (FFs).

Optionally, statistical analysis of register behavior is performed on a simulation of a test bench of the logic circuit or system to determine the correlation between toggling behavior of the registers. Correlated registers may be clustered into sets and driven by a common clock gater. Such gated clusters may themselves be clustered into correlated sets and driven by higher level gaters as required. It is noted that number of levels of a gating network and the number of registers in each cluster may be determined from an analysis such as disclosed hereinbelow.

It is noted that the systems and methods of the disclosure herein may not be limited in its application to the details of construction and the arrangement of the components or methods set forth in the description or illustrated in the drawings and examples. The systems and methods of the disclosure may be capable of other embodiments or of being practiced or carried out in various ways.

Alternative methods and materials similar or equivalent to those described herein may be used in the practice or testing of embodiments of the disclosure. Nevertheless, particular methods and materials are described herein for illustrative purposes only. The materials, methods, and examples are not intended to be necessarily limiting.

A method is presented herein for controlling clock disabling at the gate level. The clock signal driving a FF is disabled (gated) when the FF state is not subject to a change in the next clock cycle.

It is noted that additional logic and interconnects may be required to generate the clock enabling signals. Such additional elements may demand more real estate and power overheads. In a particularly extreme case, each clock input of a FF may be disabled individually, however this may result in a high overhead. In contradistinction, several flip-flops may be grouped to share a common clock disabling circuit, thereby reducing the total overhead. Nevertheless, such grouping may lower the disabling effectiveness since the clock will be disabled only during time periods when the inputs to all the FFs in a group do not change.

For a set of flip-flops, where the FFs' inputs are statistically independent, the clock disabling probability may equal the product of the individual probabilities. This product approaches zero as the number of FFs in the set increases. It may therefore beneficial to group FFs whose switching activities are highly correlated. Accordingly, a common enabling signal maybe derived for all the flip flops in the set.

The state transitions of FFs in digital systems such as microprocessors and controllers may depend on the data they process. It has surprisingly been found that assessing the effectiveness of clock gating may benefit from extensive simulations and statistical analysis of FFs activity.

Disabling the clock input to a group of FFs (e.g., a register) in data-path circuits may be particularly effective as many bits may behave in a similar manner. Registers enabled by a common clock signal may yield a high ratio of the saved power to circuit overhead. Furthermore, the design effort to create the disabling signal may thereby be reduced. In comparison to data-path, the random nature of control logic requires far greater design effort for successful clock gating.

For illustrative purposes only, and so as to better explain the effectiveness of the disclosed gating methodology, an example is presented herein of a 3D graphics accelerator and a 16-bit microcontroller. These units were designed with full awareness of the internal data dependencies and appropriate clock enabling signals were defined within the Register-Transfer Level (RTL) code. When the RTL code was then compiled and simulated at gate level, significant disabling opportunities were surprisingly discovered.

Clock gating may be applied only to the first level of gaters directly driving FFs, since the majority of the load may occur at the leaves of the clock tree where the FFs are connected. Even if the clock ceased driving all the FFs when not required, the rest of the network may continue producing clock signals and wasting energy. In contradistinction to such systems, the present disclosure implements gating at higher levels of the clock tree (closer to root). Furthermore, it has been found that other portions of the tree may also consume considerable power since they are using long and thick wires as well as intermediate drivers such that robust clock signals are produced for far end FFs.

The gating system disclosed herein may effect dynamic pruning of large portions of the clock tree if it becomes clear that none of the driven FFs along a particular branch is subject to change in the next cycle.

In order to construct a gate clock tree, it may be necessary to select a suitable fan-out structure for the gater. The fan-out structure may determine how many flip-flops are driven by each common gate driver. In addition, it may be necessary to determine which flip-flops should be grouped into a single branch of the tree and controlled by a common gater. Indeed, higher levels may further determine which sibling gaters should themselves be grouped for increased power savings.

In contradistinction to known models which generally assume a binary clock tree model, the disclosure herein uses a power model which accounts for interconnects of clock signal and the enabling (gating) signals overhead. It is particularly noted that, unlike the known approaches, a fan-out structure is derived for the clock tree which may maximize the net switching power savings and may account for the overhead incurred by the extra logic circuitry required to generate the gating signals. Sibling gaters or flip-flops to be included in each branch may be selected using a matching technique.

It is noted that FFs' toggling displays a probabilistic behavior. Accordingly, a worst case probabilistic model, may be used to yield a result to provide a lower limit for power savings.

Such a model may be uniformly applicable to any design and the actual power reduction obtained by the methodology proposed here can only be higher than that predicted by the worst case model.

It is particularly noted that the present method may test a large set of applications prior to clock tree construction in an attempt to find the probability and correlation of FF toggling. Optionally, the best-case lower bound may be followed rather than the worst case lower bound. FF toggling correlation may be used for selecting groups of flip-flops.

Unlike some modular resolution solutions, the current method may resolve gating of individual FFs at individual clock cycles. Gating at high resolution has been proposed for regularly structured circuits such as Linear feedback shift register (LFSR) and counters, where the amount of power savings can be predicted from the circuit structure.

Attempts to discover an explicit clock disabling condition have required detailed knowledge of the state transitions and state coding, based on which clock signal requirements were derived and used for gating. Such methods may be useful for simple and well-structured circuits such as counters. However this may be more difficult to apply to general control logic whose state coding assignment is usually determined by automatic synthesis tools.

Known solutions have proposed tree structures which allow gaters at each internal node, depending on the activity of the node. Such solutions are defined by combining the activities of the leaves of the tree, which are the node's children, using OR gates.

An accurate derivation of the load incurred by clock enabling is herein presented, taking into account the logic gates and the interconnects involved. Accordingly, the structure of the adaptive disabling circuits is established. These circuits may be combined in the traditional clock tree.

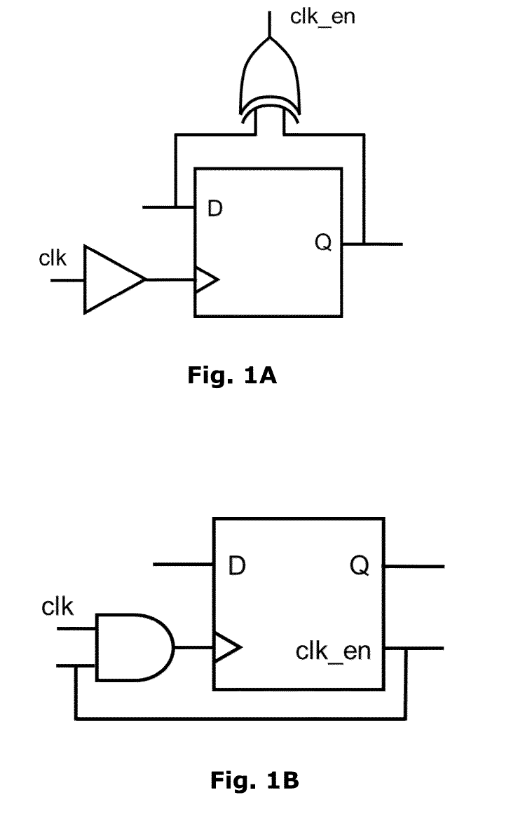

Referring now to FIG. 1A showing a FF configured to determine that its clock may be disabled in the next cycle. The flip-flop has an input D and an output Q and receives a clock signal clk from a clock driver. A XOR gate is configured to compare the FF's current output with the present data input that will appear at the output in the next cycle. Accordingly, the output Q and input D of the flip flop provide two inputs to the XOR gate such that the XOR's output clk_en indicates whether a clock signal will be required in the next cycle. It is noted that the internal master of the flip-flop may provide an alternative input for the XOR gate rather than the input D, such a configuration may provide additional stability particularly when the flip flop's slave is transparent.

With reference to FIG. 1B, a clock enabling flip flop is represented showing the clk_en signal as an additional output of the flip-flop itself. The clk_en signal may be used to enable the clock driver by introducing a two-way AND gate, known as a clock gater, to drive the clock. The clock signal clk and the clock enable signal clk_en provide inputs for the clock gater, accordingly the clock is only triggered when both a clock signal clk and a clock enable signal clk_en are received.

Power consumption of a system may be reduced further by grouping flip-flops together into sets and providing all flip-flops in the set with a common gater. Synthesizers may be used during the physical design phase of the system to provide groupings, although these are generally directed towards reducing skew, power and area without considering the underlying correlations between the flip-flops themselves.

It is a particular advantage of the current disclosure that correlated flip-flops which generally toggle simultaneously may be grouped together and controlled by a common gater. Such an arrangement may reduce the number of redundant clock signals required by the system and accordingly provide still further power reduction.

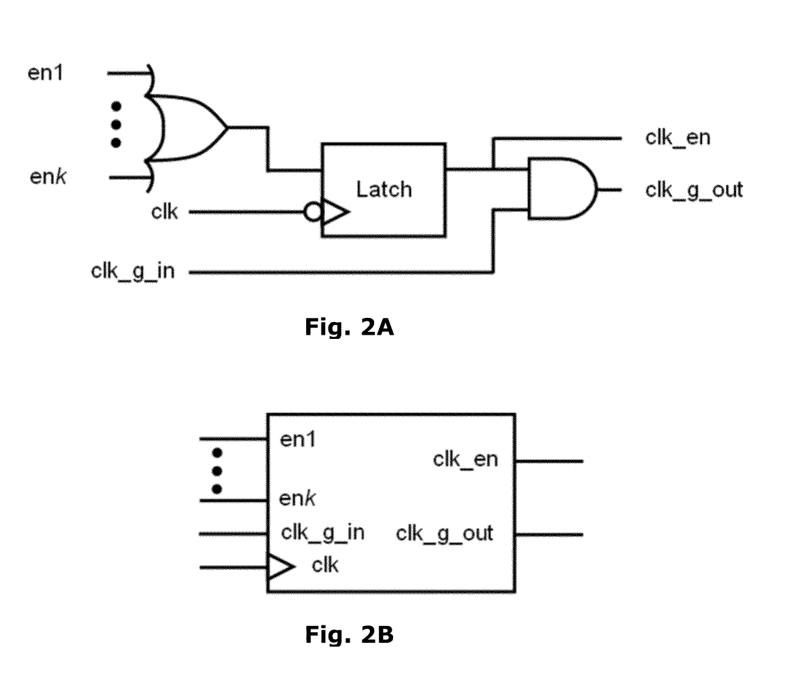

Referring now to FIG. 2A, a possible gate configuration is presented which may be used to combine multiple clk_en signals generated by distinct FFs into one gating signal. Such an arrangement may save the individual clock gaters at the expense of an OR gate and a negative edge triggered latch that may be used to avoid glitches of the enable signal. The combination of a latch with an AND gate is termed an integrated clock gate (ICG) and may be represented by the symbol shown in FIG. 2B.

It has been found that when the power consumed by the latch is taken into consideration, such a combination may be justified where more than two clk_en signals are to be combined. The hardware savings of such as system increase the more clk_en signals that are combined, however the number of disabled clock pulses decreases.

Accordingly, the current disclosure may enable a greater number of clock enabling signals to be combined by providing a higher degree of correlation between the grouped flip-flops in any set.

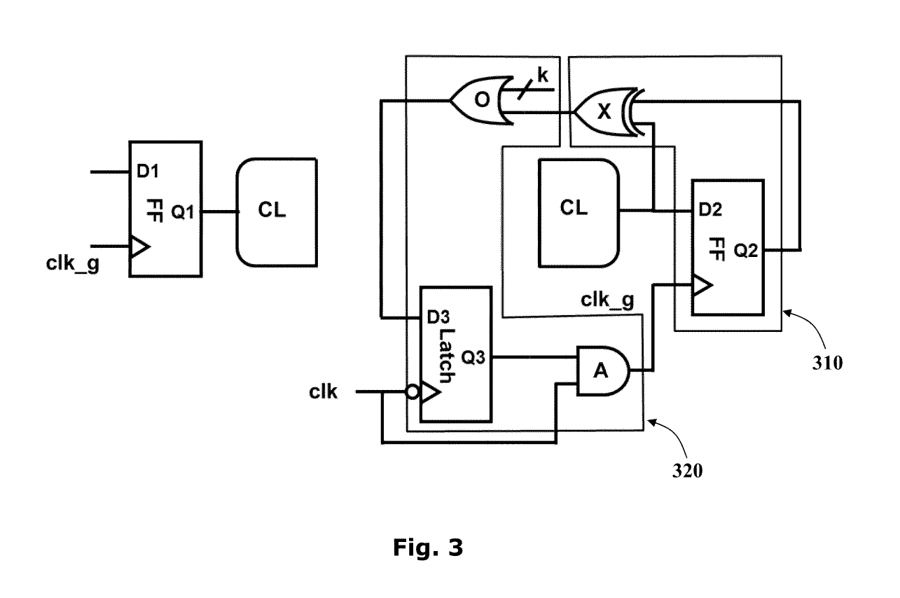

The adaptive clock gating of the disclosure has considerable timing implications. Reference is now made to FIG. 3, illustrating a FF to FF logic stage with its driving clock signals. The logic stage of FIG. 3 includes a clock gater 320 and a flip-flop 310. The XOR gate may be integrated into the FF, while the OR gate, AND gates and the latch are integrated into the clock gater.

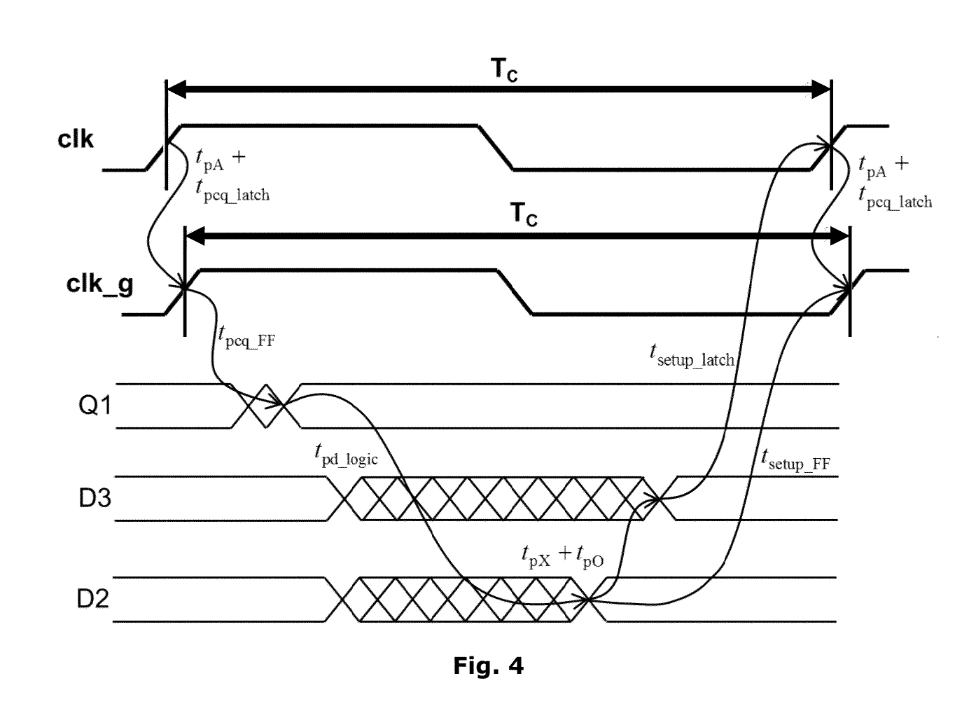

Referring now to FIG. 4 the timing sequence and its implied constraints are depicted. There are two distinct clock signals: clk_g is the ordinary gated signal driving the registers, while clk is a signal driving the latches of the clock gaters.

It is noted that, in order to provide proper operation, the time period may be limited by the following constraint:

t_{pcq}_{_{—}}_{FF}+t_{pd}_{_{—}}_{logic}+tₛₑₜᵤₚ_{_{—}}_{FF}≦T_{C} (1)

where t_{pcq}_{_{—}}_{FF} represents the propagation delay time of a flip-flop, t_{pd}_{_{—}}_{logic} represents the propagation delay time of the logic stage between two flip-flops and tₛₑₜᵤₚ_{_{—}}_{FF} represents the set up time of a flip-flop.

This is the constraint used in VLSI design practice, without adaptive gating, that is imposed by clk_g. The introduction of gating may result in the following constraint being required for proper latching of the enabling signal:

t_{pA}+t_{pcq}_{_{—}}_{latch}+t_{pcq}_{_{—}}_{FF}+t_{pd}_{_{—}}_{logic}+tₚₓ+tₚ₀+tₛₑₜᵤₚ_{_{—}}_{latch}≦T_{C} (2)

where t_{pA} represents the propagation delay time of the AND gate, t_{pca}_{_{—}}_{latch} represents the propagation delay time of the latch, a flip-flop, tₚₓ represents the propagation delay time of the XOR gate, tₚ₀ represents the propagation delay time of the OR gate and tₛₑₜᵤₚ_{_{—}}_{latch} represents the set up time of the latch.

It follows from (1) and (2) that:

t_{pcq}_{_{—}}_{FF}+t_{pd}_{_{—}}_{logic}+T′≦T_{C} (3)

where T′=max{tₛₑₜᵤₚ_{_{—}}_{FF}, t_{pA}+t_{pcq}_{_{—}}_{latch}+t_{pX}+tₚ₀+tₛₑₜᵤₚ_{_{—}}_{latch}}

Equation (3) may impose certain constraints upon the setup times of the latch and FF and the delay of the gating logic. Furthermore, it may happen that (2) will not be satisfied unless the clock period is relaxed or the logic propagation delay stays small enough.

It is noted that the method described herein may allow such timing limitations to be identified during simulation phase. It is further noted that such limitations may be overcome within the system by providing a manual override of the gating of problematic registers thus identified within the system.

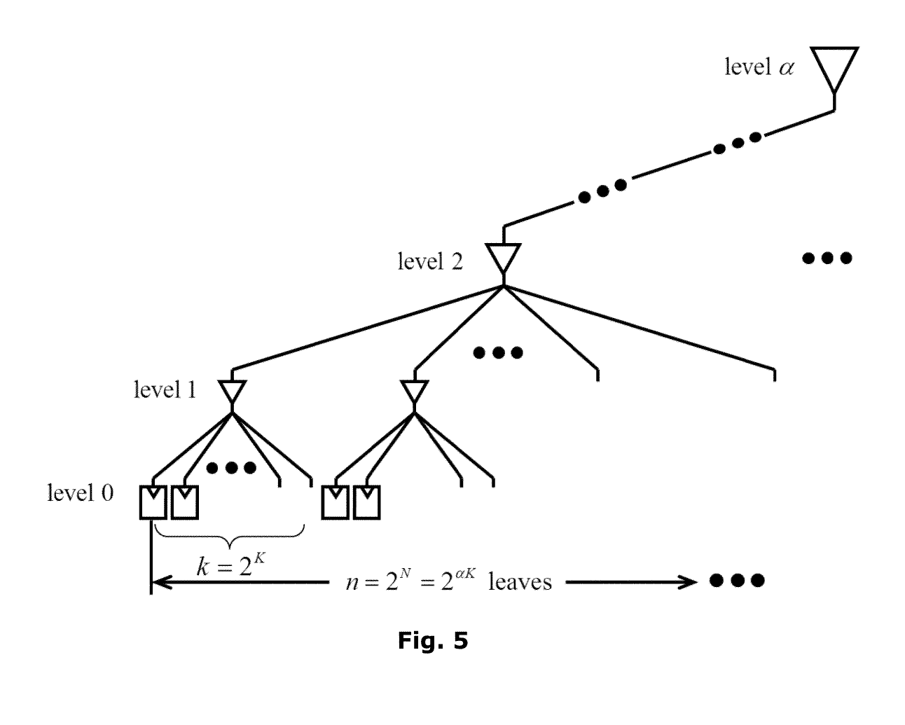

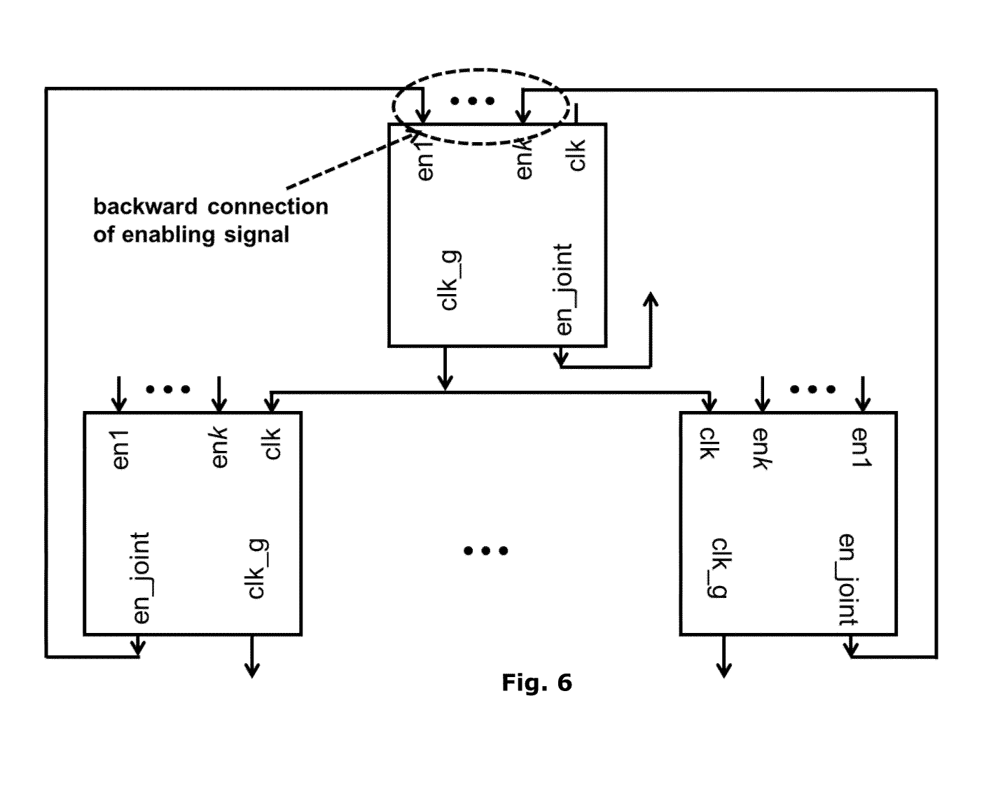

Joining enabling signals of individual FFs may suit a clock tree distribution network such as shown in FIG. 5, for example. The clock signal may enter the block at a pin called root, and is then driven to the far-end FFs along chains of drivers connected in a tree topology. It is noted that the drivers of the tree may be replaced by k-way gaters such as shown in FIG. 6. Each gater receives the enabling signals of its k children and delivers the clock signal downstream accordingly.

A possible circuit may contain, say, n=2^{N} FFs whose clock signals are driven by the tree shown in FIG. 5. Its leaves are connected to the FFs and the gaters' fan-out is k=2^{K}, where N=αK and α is the number of levels of the clock tree. A leaf gater has unit size (driving strength). The gater at the first level is connected to the leaf by a wire of unit length and unit width. The following notations are introduced to quantify and analyze the power savings achieved by joint clock enabling: C_{FF}—FF's clock input capacitance, c_{latch}—latch capacitance, including the wire capacitance of its clk input, c_{w}—unit wire capacitance, c_{gater}—unit drive gater capacitance, c_{OR}—OR gate capacitance, β—level to level gater's sizing factor, γ—level to level wire width sizing factor, δ—level to level wire length sizing factor.

In this notation the size of a gater in level j is β^{j-1} and the size of a wire connecting level j to j−1 is (γδ)^{j-1}, 1≦j≦α, as commonly happens in tree networks such as the H-tree. The total capacitive load of the resulting clock tree is:

$${C}_{tree} = {nc}_{FF} + {c}_{gater} {\sum }_{j = 1}^{α} ( \frac{n}{{k}^{j}} ) {β}^{j - 1} + {c}_{w} {\sum }_{j = 1}^{α} ( \frac{n}{{k}^{j - 1}} ) {( γ δ )}^{j - 1} = n [ {c}_{FF} + \frac{{c}_{gater}}{β} \frac{1 - {( β / k )}^{α}}{1 - β / k} + {c}_{w} \frac{k}{γ δ} \frac{1 - {( γ δ / k )}^{α}}{1 - γ δ / k} ] \qquad ( 4 )$$

Consider for example the well-known clock H-tree, for which k=4 (K=2). To illustrate (4) and examine the relative contribution of the various capacitances to power consumption let n=1024 and then N=10 and hence α=5. Setting β=2, γ=2 and δ=4 yields Cₜᵣₑₑ=1024(c_{FF}+c_{gater}32/31+c_{w}31/2).

To assess the clock gating impact on power we consider the toggling of FF as an independent random variable. A FF has probability p to change state and q=1−p to stay unchanged. The probability of a group of k FFs to stay unchanged (as a group) is therefore q^{k}. The probability p is sometimes called activity factor. The average activity factor of non clock signals is very low, since a typical signal toggles very infrequently.

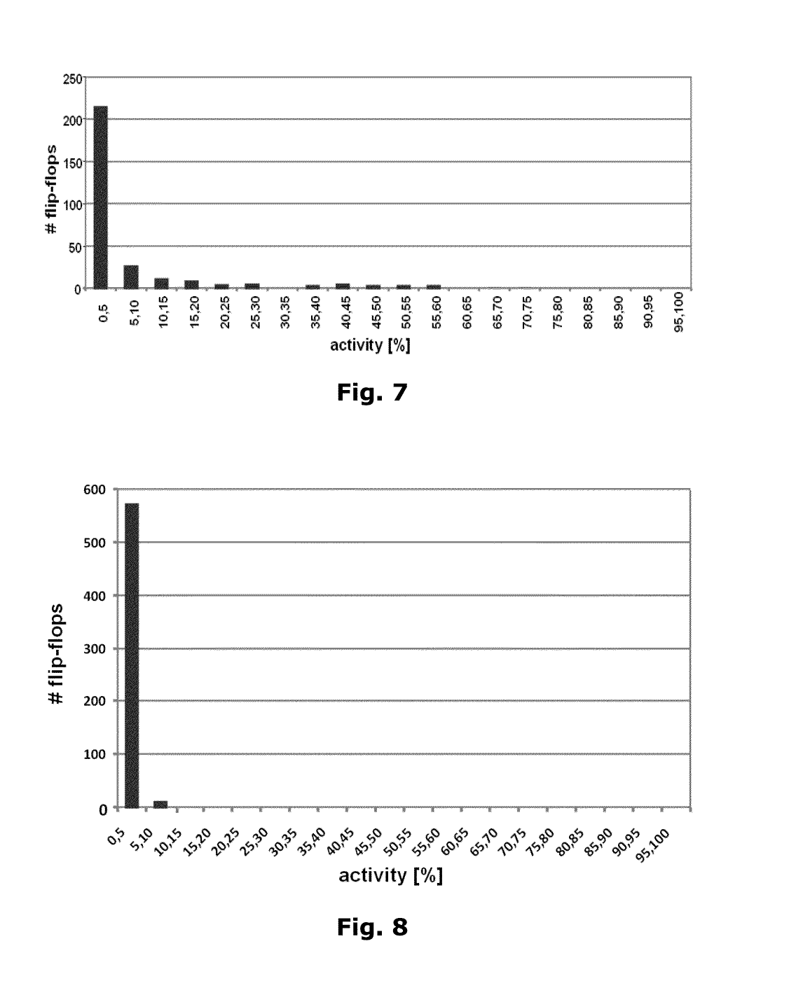

The toggling probabilities of individual FFs may be obtained by running gate-level simulation with a representative test bench of the application in hand. This is demonstrated in the graph of FIG. 7 that shows the activity factors measured for a 16-bit microcontroller. A test bench of its instruction set has been simulated and the toggling of every FF in its ALU and control circuits (register file was excluded) was recorded. As shown, the majority of FFs are toggling a very small fraction of time, less than 5%. Similar statistics are shown in FIG. 8 for a triangle's rasterization unit used in a 3D graphics accelerator.

A gater at level j of the tree may drive k child gaters of size β^{(j-2)} and k wires of size (γδ)^{(j-2)}. Since the number of FFs spanned by that gater is k^{j} (the number of leaves in the sub-tree rooted at that gater), the probability of a disabling clock signal is q^{k}^{^{j}}. The dynamic power saved by the gater is the product of its disabling probability and the capacitive load it is driving. This load is given by kq^{k}(c_{FF}+c_{w}) for first level gater and by kq^{k}^{^{j}}[c_{gater}β^{j-2}+c_{w}(γδ)^{j-1}] for the second level and above. There are n/k^{j} nodes at level j of the tree. Let α′≦α a be the highest gated level. The total power savings C_{saving}^{1-α′} resulted by replacing the ordinary drivers by clock gaters are considered, without accounting for gating logic and interconnects overhead. This may be obtained by summation of the savings over all nodes of the gated levels, given by:

C_{saving}^{1-α′}=n(c_{FF}+c_{w})q^{k}+Σⱼ₌₂^{α′}(n/k^{j-1})q^{k}^{^{j}}[c_{gater}β^{j-2}+c_{w}(γδ)^{j-1}]. (5)

Clock gating incurs a certain power and area cost. As shown in FIGS. 1, 2 and 3, FFs need additional XOR gates and every gater requires a k-way OR gate and a latch. Moreover, there is a wiring penalty resulting from the separation of clk_g and clk. The interconnections realizing clk_g are switching only when the clock is required for FF toggling. These are the real functional clock wires with the full sizing required to deliver high quality clock signal. The interconnections propagating clk are needed for the latches residing at the gaters and are used at each cycle. Notice that clk exists only from gaters at the first level of the tree and above, but does not exist at the leaves (FFs). There are also the clk_en signals, feeding back the activity of k children gaters (or FFs at leaves) to the OR gate at their parent. The wires of clk and clk_en, shown in FIG. 6, may generate a “shadow” of the clock tree in FIG. 5. These wires may be of a minimum width, subject to delay constraints shown in FIG. 4. A reasonable assumption for the subsequent analysis is that their length is similar to that of clk_g since they connect the same elements as clk_g does.

The calculation of the power consumed by the shadow tree with its logic overhead is based on toggling probabilities. An enabling signal informs the gater at level j whether its child gater at level j−1 needs the clock pulse in the next cycle. The toggling independence is a worst case assumption since toggling correlation increases power savings as it reduces the probability of a gater to send a clock signal to a FF when it does not need it. We calculate the net power savings, denoted by cₙₒₜ_{_{—}}_{saving}^{j}, 1≦j≦α′, for a single branch of the tree and then sum over all branches. At the leaves where FFs are connected (j=1), the net power savings per branch satisfies:

cₙₑₜ_{_{—}}_{saving}¹≧q^{k}(c_{FF}+c_{w})−[c_{latch}/k+(1−q)(c_{w}+c_{OR})]. (6)

The term _{q}^{k}(c_{FF}+c_{w}) in (6) is the savings due to the disabling of clk_g. The term c_{latch}/k is the overhead due to the latch at the parent gater being always clocked by the clk signal. The division by k stems from the fact that the latch overhead is amortized among the k branches connected to the gater. The overhead (1−q) (c_{w}+c_{OR}) is due to the switching of clk_en. It is noted that the probability of a FF to toggle is p=1−q, then Pr (clk_en=1)=1−q and hence its switching probability may not exceed 1−q.

For the internal nodes of the tree (j≧2) a similar analysis maybe followed as performed for j=1. It is shown in (5) that the savings for a forward branch of clk_g due to its disabling probability q^{k}^{^{j}} is given by:

c_{saving}^{j}=q^{k}^{ⱼ}[c_{gater}β^{j-2}+c_{w}(γδ)^{j-1}], (7)

where c_{gater} and c_{w} are multiplied by their appropriate sizing factors.

In parallel to the forward clock signal clk_g, there is a “shadow” feedback enabling signal clk_en, issued from the latch output of the (j−1)-level gater (see FIG. 2), driving one of the k-input OR gate of the j-level gater, whose output is latched at level j. The latch at level j is always clocked by clk, but it is amortized among the k forward branches of the gater. clk_en is 1 when its corresponding (j−1)-level gater needs the clock signal in the next cycle and 0 if it does not. Since the toggling probability of the (j -1)-level gater is 1−q^{k}^{^{j−1}} it follows that Pr (clk_en=1)=1−q^{k}^{^{j−1}} and hence its relative switching count cannot exceed 1−q^{k}^{^{j−1}}.

In summary, the power overhead per branch to generate the enabling signal is given by:

c_{ovehaed}^{j}=c_{latch}/k+(1−q^{k}^{^{j−1}})[c_{w}(γδ)^{j-1}+c_{OR}], 2≦j≦α′. (8)

It is noted that a worst case assumption may be made by using the same sizing factor (γδ)^{j-1} for clk_en wire as for clk_g. Subtraction of (8) from (7) yields the net power savings per branch as follows:

$${c}_{net \_ saving}^{j} \geq {q}^{{k}^{j}} [ {c}_{gater} {β}^{j - 2} + {{c}_{w} ( γ δ )}^{j - 1} ] - \{ {c}_{latch} / k + ( 1 - {q}^{{k}^{j - 1}} ) [ {{c}_{w} ( γ δ )}^{j - 1} + {c}_{OR} ] \} , 2 \leq j \leq {α}^{′} . \qquad ( 9 )$$

It is noted that (6) can be obtained from (9) by substituting j=1 and replacing c_{gater}β^{j-2} with c_{FF}.

The total net power savings cₙₑₜ_{_{—}}_{saving}^{1-α′} in a clock tree gated up to level α′ is obtained by summation of the net savings over all branches of the gated levels. There are n wires connected to FFs whose savings is given in (6), and n/k^{j-1} wires connected from level j to level j−1 for 2≦j≦α′, whose savings is given in (9), thus yielding:

cₙₑₜ_{_{—}}_{saving}^{1-α′}=ncₙₑₜ_{_{—}}_{saving}¹+Σⱼ₌₂^{α′}(n/k^{j-1})cₙₑₜ_{_{—}}_{saving}^{j}. (10)

The importance of equation (10) stems from the fact that it describes the relationship between the clock signal disabling probabilities and the circuit's capacitance factors on one hand, and the clock tree structural parameters (gater's fan-out k) on the other hand. This enables the construction of a clock tree that yields maximum power savings. Solving the equation (d/dk)cₙₑₜ_{_{—}}_{saving}^{1-α′}=0 yields the optimal k. This equation is complex and not analytically solvable but can be solved numerically.

The common case in logic-gate design-level is considered where clock gating takes place at the first level of the tree. Such gating is what is currently supported by several CAD tools, leaving to the user the decision regarding the value of k, usually by relying on past experience. Equating to zero the derivative of (6) with respect to k yields the following implicit equation for the optimal k:

q^{k}1n q(c_{FF}+c_{W})+c_{latch}/k²=0 (11)

It is noted that the gating overhead term (1−q)(c_{w}+c_{OR}) appearing in (6) does not affect the optimal k since it is being paid by each of the n FFs, regardless of the value of k.

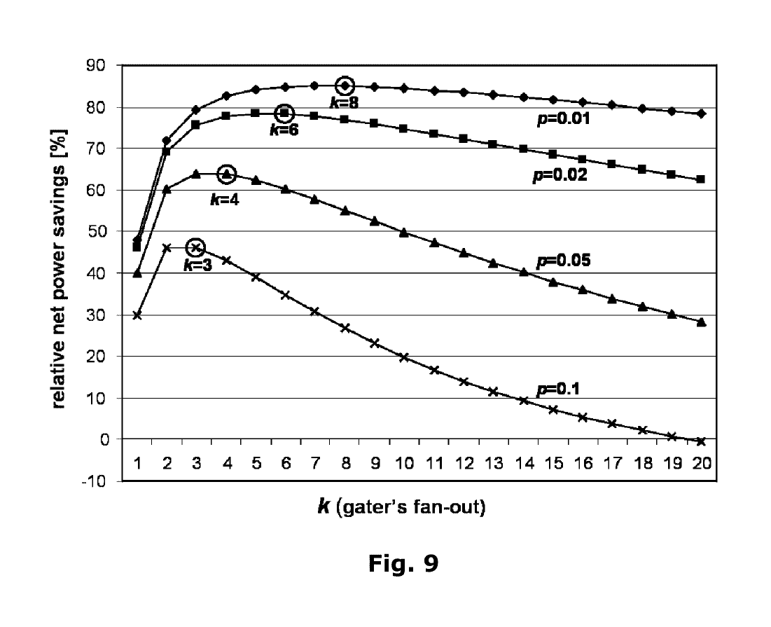

In an attempt to find the optimal value of k, FIG. 9 shows the normalized power savings per FF derived from (6). The savings are compared to the non gated situation. Various values of q=1−p have been examined to explore the behavior of the optimal k. The relative capacitance of FFs, latches, OR gate and unit wires connecting the first level gater to the FFs depend on the specific technology and cell library in hand. We assumed all to be equal in FIG. 9. As expected, the lower the toggling probability of FF is, the higher the optimal k is. The optimal k values obtained in the plots agree with the common practice of EDA tools. It is shown that significant savings can be achieved. Recall however that there are delay and area overhead costs and though high fan-out values result in less gaters, the OR fan-in is increasing accordingly, which will further increase area and delay overheads.

An implementation of adaptive gating has been reported where, after taking into account the power consumed by the extra circuitry, a 10% net power savings was reported. Similar amounts of savings may be observed based on gate-level simulations of designs, where adaptive gating was added to the first level of clock gater. This translates to 5% of total dynamic power savings of the entire chip. The net savings were obtained on top of savings obtained by clock enabling signals which have already been introduced by the designer at the RTL verilog.

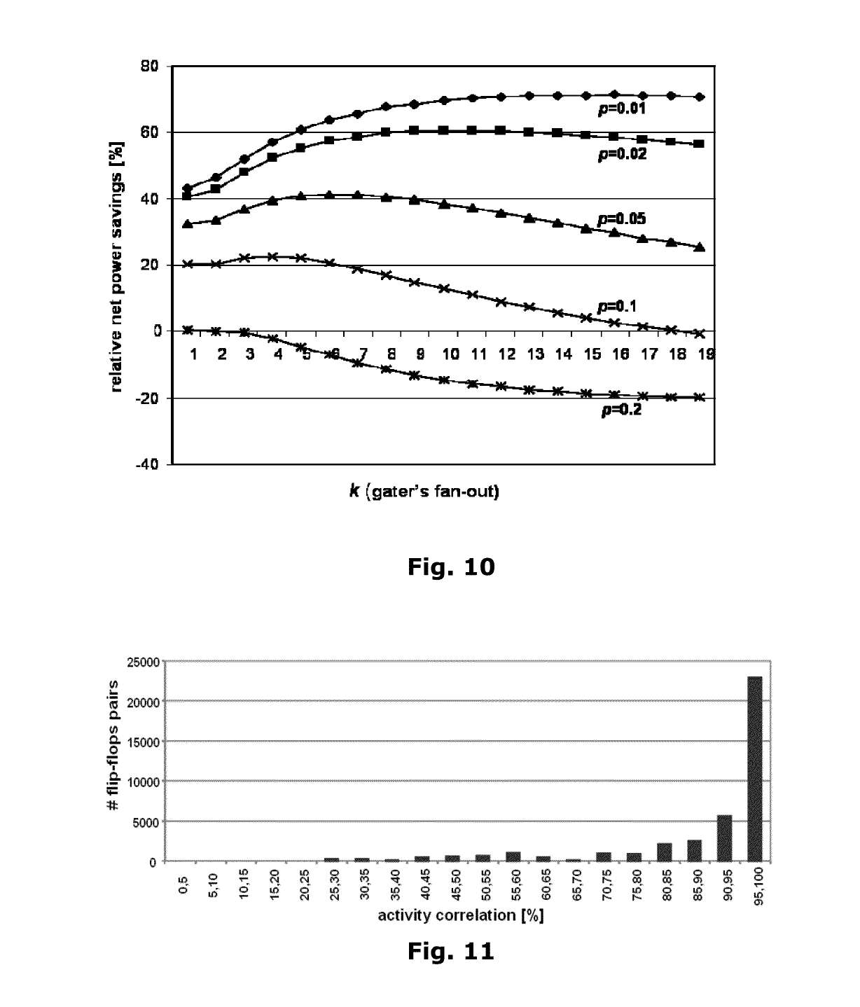

Additional savings may be obtained by gating at higher levels of the tree. The normalized net power savings per FF for gating at three levels is illustrated in FIG. 10 as a percentage of the non gated situation. There, gater's drive, wire width and wire length sizing factor of β=\sqrt{2}, γ=\sqrt{2}and δ=2, respectively, have been used. As can be seen higher power savings per FF are achieved by gating at the 2^{nd} and 3^{rd} levels. For low toggling probabilities more power savings is obtained. Though the percentage may be lower than in FIG. 9, the total is higher since it is taken from lager capacitance. On the other hand, once FFs toggling probabilities increases, the savings turns rapidly down, and for p>0.2 there's only power loss. The area implications of the proposed scheme for acceptable values of the fan-out need to be further investigated by incorporating it into a backend layout flow.

Regarding the gating depth α′, it is noted that the term q^{k}^{^{j}} in (9) rapidly approaches zero with increasing j, turning cₙₒₜ_{_{—}}_{saving}^{j} into a negative value. This in turn results in power waste rather than savings as can be seen in FIG. 10. Accordingly, where appropriate, adaptive gating may be restricted to the lower levels of the clock tree.

Regarding latency, it is noted that timing constraints applicable for FFs at the leaves of the clock tree have been derived in (1)-(3). In the proposed gating scheme, the next cycle enabling signals are bottom-up propagated in the “shadow” tree towards its root. Each node in a path from leaf to root determines whether it needs the clock signal clk_g for the next cycle and then transmits its decision to its parent. clk_g is then delivered through the main clock tree from the root down to the FFs. The delay of this round trip must fall within a single clock cycle, which is unlikely to happen for a high clock speed and a clock tree comprising many levels. This may present further motivation for restricting adaptive gating to lower levels of the clock tree where appropriate.

A probabilistic model of adaptive gating is developed herein deriving expressions for the optimal gater's fan-out. A worst-case assumption was made that the FFs are toggling independently of each other. In reality, toggling of FFs may be correlated to some degree, which can increase the power savings in (10). This follows from the disabling probabilities appearing in the positive terms of (6) and (9) that can only become greater than q^{k}^{^{j}}, while the feedback toggling probabilities appearing in the negative terms may obtain smaller than 1−q^{k}^{^{j−1}}.

A further step is to decide on the groups of k FFs to be driven by a common clock signal, and similarly determine the grouping of internal tree gaters when constructing the entire clock tree shown in FIG. 5.

FFs and gaters groupings have logic and physical aspects. The logic aspect attempts to minimize the number of clock pulses delivered to FFs and gaters when they are not needed; these are called redundant clock pulses. The physical aspect has to do with the on-die locations of FFs and gaters which directly affect the amount of routing required for their connection, and hence their capacitive load, delay and clock skew.

Solving the logic aspect has been shown to be an NP-complete problem and hence a heuristic solution is in order. In this section we present an approach towards a practical solution. It is possible to construct an example where this heuristic would increase the number of redundant clock pulses rather than minimize them. FFs and gaters may be paired based on intuitive arguments which may sometimes yield inferior gating. It is further noted that for a binary tree the FF pairing at leaves can be optimally solved using a minimum weight perfect matching algorithm.

A scheme may construct clock trees when the positions of the leaves known. The leaves can be FFs or modules' input clock pins for higher design levels. Clock activities and clock pin distances are weighted and summed, but this is problematic since the physical meaning of a weighted sum is not well defined and requires delicate setting of the weights. It is also possible to generate an example where the weighted pairing heuristic yields the worst solution. It is believed that summing of products of activity by distance is more appropriate since it explicitly measures power consumption and no weights are needed.

Considering the logic aspect, let a circuit run for T+1 clock cycles. Let the vector a=(α₁, . . . , α_{T}) denote the activity of a FF, where αₜ=0 , 1≦t≦T if the FF stays unchanged (no toggling) from t−1 to t, and αₜ=1 otherwise. The norm ∥a∥ is the number of 1s in a, which is proportional to the power consumed by FF switching. Each of the n(n−1)/2 FF's activity pairs (aᵢ,aⱼ), 1≦i<j≦n, are bit-wise XORed and ∥aᵢ⊕aⱼ∥ is therefore the number of redundant clock pulses occurring if FFᵢ and FFⱼ are jointly clocked by the same gater. Two correlations are defined. The first equals 1−∥aᵢ⊕aⱼ∥/T, measuring FFs pair activity correlation during the entire period T. For FFs whose toggling rate is very law this value is nearly 1, regardless of their joint toggling similarity. The second correlation equals 1−∥aᵢ⊕aⱼ∥/∥aᵢ|aⱼ∥(where the OR is a bit-wise operation), measuring their joint toggling.

Large values of those indicate of high potential of joining FFs for a common drive such that the number of redundant clock pulses is reduced, thus yielding higher power savings.

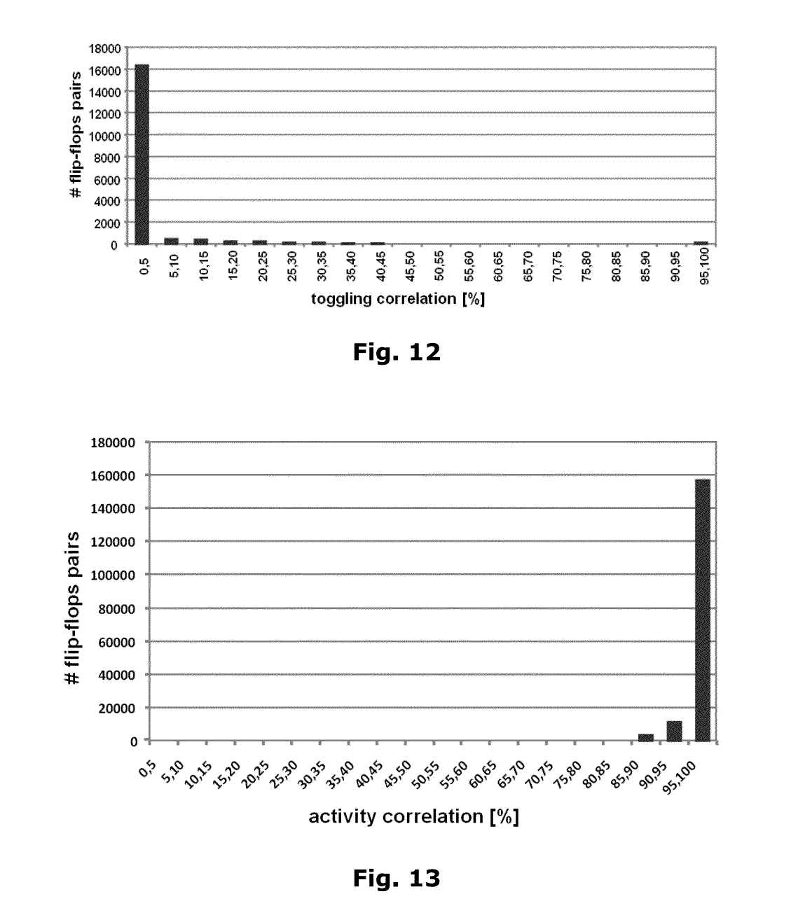

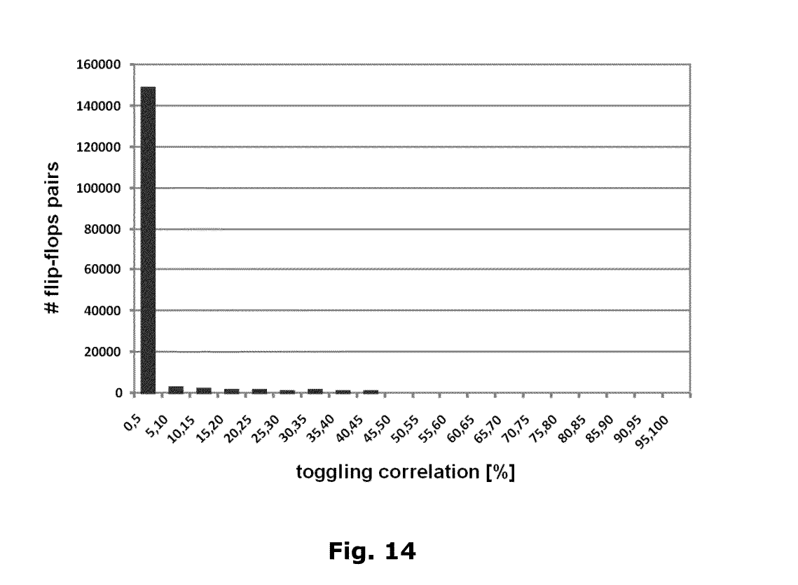

The toggling correlations of the FFs in a 16-bit micro-controller whose activities are shown in FIG. 7, have been measured. FIG. 11 shows the 1−∥aᵢ⊕aⱼ∥/T activity correlation metric. For the majority of pairs this value is nearly 100%. This happens since their toggling probability is very low and hence ∥aᵢ⊕aⱼ∥<<T. FIG. 12 shows the joint toggling correlation. Indeed, there are many FFs pairs that can be driven by a common gater with low redundant clock pulses. The related correlations measured for the triangle's rasterization unit of a 3D graphics accelerator shown in FIG. 8 are illustrated in FIGS. 13 and 14, with similar activity and toggling correlations.

In order to group FFs at the leaves, and similarly gaters at the tree's internal nodes, the case of k=2 is addressed initially. A weighted complete graph G(V,E,w) is defined as follows. A vertex vᵢεV corresponds to FFᵢ and an edge eᵢⱼεE connecting two vertices vᵢ,vⱼεV, 1≦i<j≦n, is associated with a weight w(eᵢⱼ)=∥aᵢ⊕aⱼ∥. The weight represents the number of redundant clock pulses driving FFᵢ and FFⱼ, resulting from being clocked by a common gater. The optimal FF pairing is therefore equivalent to covering V by n/2 edges of minimum weight sum. This is the well-known minimal perfect matching problem.

FIGS. 7 and 8 which show a very small average toggling probability, and the gater's optimal fan-out obtained from equations (11) and (10), and depicted in FIGS. 9 and 10, respectively, indicate that k should be usually greater than 2 and the minimal perfect graph matching model must therefore be modified. At each level of the hierarchy, a complete graph with half the number of vertices than in its lower level is defined. A vertex is associated with a toggling vector defined by the union (bit-wise ORing) of its two children, while an edge is weighted by the number of redundant clock pulses incurred by driving the two graph's vertices through a joint gater. Though intuitive, it does not yield the optimal grouping.

To consider the matching of k>2 vertices in an attempt to minimize the amount of redundant clock pulses, we can use a complete k -uniform hyper graph H(V,E,w), modeling the “toggling proximity” of FFs groups as follows. A hyper edge e(V′)εE, V′⊂V, satisfies |V′|=k. Denote by aᵥ the toggling vector of FFᵥ, vεV. The weight of a hyper edge represents the number of redundant clock pulses driving V′'s FFs, and is given by:

$$w ( e ( {V}^{′} ) ) = {\sum }_{v ∈ {V}^{′}} ‖ {a}_{v} ⊕ {⋃}_{u ∈ {V}^{′}} {a}_{u} ‖ . \qquad ( 12 )$$

The union in (12) is the bit-wise ORing of the k toggling vectors, while XORing the union with an individual toggling vector aᵥ yields the redundant clock pulses driving FFᵥ. It follows that

$$\vert E \vert = ( \begin{matrix}n \\ k\end{matrix} )$$

and the problem of finding the n/k hyper edges covering the n vertices and yielding minimum redundant clock pulses turns into an NP-complete minimal weight exact covering problem and any approximation of the latter will apply.

As mentioned before the “logic proximity” must be accounted together with some knowledge on the proximity of FFs. Weighing H(V,E,w) hyper edges by product of a distance measure (e.g., the diameter of the circle enclosing FFs) and the count of redundant clock pulses in (12) is suggested. It directly measures the wasted switching power.

Accordingly, a probabilistic model of the clock gating network is presented that allows quantifying the expected power savings and the implied overhead. It was surprisingly found that under reasonable and realistic assumptions, supported by simulations of real VLSI designs, a fan-out of a gater may be derived which increases power saving. Such a derivation may be based on a statistical analysis of the toggling probability of the FFs comprising the circuit, the relative capacitance factors of the process technology and cell library in hand, and the sizing factors used in the clock tree construction.

Although where the toggling of FFs is independent of each other and in case of high FFs activity, the gater's fan-out may be very small, a model for the optimal fan-out may be developed where a certain correlation exists. This may allow the fan-out to be increased to achieve higher power savings. Furthermore, FFs may be combined into groups of a particularly effective size as described herein.

It is noted that data-driven adaptive clock gating, may be employed for FFs at the gate-level. The clock signal driving a FF is disabled (gated) when the FF's state is not subject to change in the next clock cycle. A model is presented herein for the data-driven adaptive gating based on the toggling activity of the constituent FFs. Thereby an optimal fan-out of a clock gater may be derived yielding maximal power savings based on the average toggling statistics of the individual FFs and the capacitance factors associated with the process technology and cell library in use.

In general, the state transitions of FFs in digital systems depend on the data they process. Assessing the effectiveness of clock gating requires therefore, extensive simulations and statistical analysis of FFs' activity.

Another grouping of FFs for clock switching power reduction, known as Multi-Bit Flip-Flop (MBFF), attempts to physically merge FFs into a single cell such that the inverters driving the clock pulse into its master and slave latches, are shared among all FFs in a group. MBFF grouping is driven by the physical position proximity of the individual FFs. Additionally or alternatively, a grouping may be proposed which combines toggling similarity with physical position considerations.

The problem is considered herein of finding the FF groupings such that the resulting power saving is increased. The backend design flow implementation is described.

In data-driven adaptive clock gating, the clock enabling signals may be understood at the system level sufficiently that they may be effectively defined to identify the periods where functional blocks and modules do not need to be clocked. Those are later being automatically synthesized into clock enabling signals at the gate level. However, when modules at a high level are clocked, the state transitions of their underlying FFs depend on the data being processed. It is noted that the entire dynamic power consumed by a system stems from the periods where modules' clock signals are enabled. Therefore, regardless of how small the relative size of this period, assessing the effectiveness of clock gating may require extensive simulations and statistical analysis of FFs toggling activity.

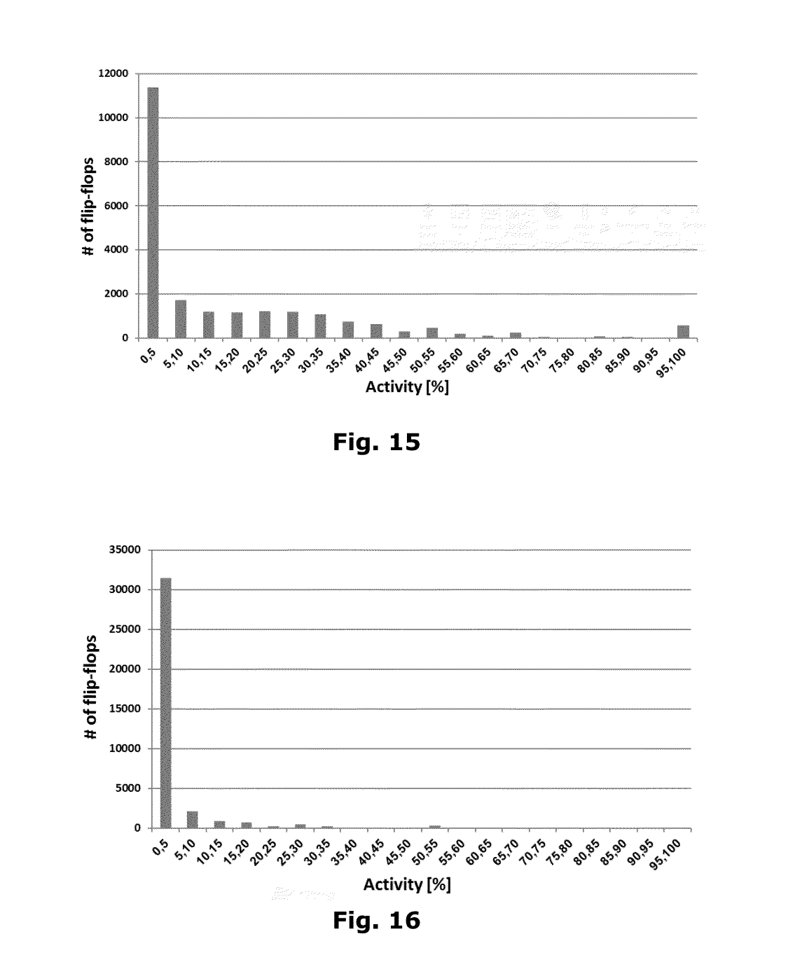

By way of illustration, FIG. 15 shows a graph representing FFs' toggling activity in an industrial DSP block designed in 40 nm technology, comprising 22K FFs, in the time windows when their clock signal was enabled. The statistics were derived from extensive simulations of typical modes of operation, consisting of 240K clock cycles. The average time window when the clock signal was enabled was only 10%, but it is anyway responsible for the entire dynamic power consumed by that block. Within that period, a FF toggled its state only 1.6% of the time on the average, thus more than 98% of the clock pulses were useless. Such a low toggling rate (of non-clock signals) is very common. FIG. 16 represents another example of a 40 nm control block of an industrial network processor, comprising 37K FFs. There, the clock signal was enabled 20% of the time, but within that window the average FF toggling was only 1.3% of the time, thus more than 98% of the clock pulses were wasteful. It follows from the above examples that no matter what clock enabling signals are defined at high design levels, there are still many opportunities to gate the clock signal at the FF level.

Referring back to FIG. 3 a possible circuit is illustrated for providing a FF to FF logic stage with its driving clock signals and a practical implementation of the gating logic. A FF finds out that its clock can be disabled in the next cycle by XORing its output with the present data input that will appear at its output in the next cycle. The XOR's output indicates whether a clock signal will be required in the next cycle. The outputs of k XOR gates are ORed to generate a joint gating signal, which is then latched to avoid glitches. The AND gate is driving the clock input of the k FFs.

It is noted that, for the scheme proposed in FIG. 3 to be beneficial, the clock enabling signals of the grouped FFs should preferably be highly correlated, or the toggling probability of each FF in a group should be very low. FFs toggling correlation is a key for maximizing the power savings by data-driven gating, and is considered herein. Grouping FFs for joint clock gating has been considered as a part of the physical layout synthesis. It is noted that such treatment generally focuses on skew, power, and area minimization, but are not aware of the toggling correlations of the underlying FFs. Equations (6) and (11) assume a worst-case scenario where the switching of FFs is independent of each other. In reality, FFs may have some toggling correlation, which will only increase the power savings. Data-driven clock gating has surprisingly been shown to achieve savings of more than 10% of the total dynamic power consumed by the clock tree.

As noted herein, the FFs of a system may be clustered into k-size sets such that the power savings will be maximized. The optimal value of k was obtained from (11) under toggling independence assumption, but in reality the toggling may be correlated. Furthermore, a practical design methodology should preserve the integrity of the clock domains defined by system clock enabling signals. This mean that the FFs of a k-size set must all belong to the same clock domain, and the optimal grouping of FFs into k-size sets should be restricted to clock domains.

A clock domain is considered having n FFs and be enabled during m+1 cycles. A first step towards an optimal FFs grouping may be to take advantage of the correlations of their toggling. The vector a=(a₁, . . . , aₘ) denotes the activity of a FF, where αₜ=0, 1≦t≦m, if the FF stays unchanged (no toggling) from t−1 to t, and αₜ=1 otherwise. The norm ∥a∥ is the number of 1s in a , which is proportional to the power consumed by the FF's switching. All the n(n−1)/2 pairs (aᵢ,aⱼ), 1≦i<j<z, are bit-wise XORed to yield the number ∥aᵢ⊕aⱼ∥ of redundant clock pulses occurring if FFᵢ and FFⱼ are clocked by a common gater. The term rᵢⱼ=∥aᵢ⊕aⱼ∥/m measures the fraction of redundant clock pulses that will occur if FF, and FF are clocked by a common gater. This fraction satisfies 0<rᵢⱼ<1 and also, rᵢⱼ≠0 and rᵢⱼ≠1 as otherwise FFᵢ and FFⱼ would toggle simultaneously or oppositely, respectively, so one FF could have been removed at synthesis. A key consideration in selecting FFs to be driven by a common gater is their activity similarity given by 1−rᵢⱼ. The closer to 1 this is, the more desirable it is to jointly drive FFᵢ and FFⱼ.

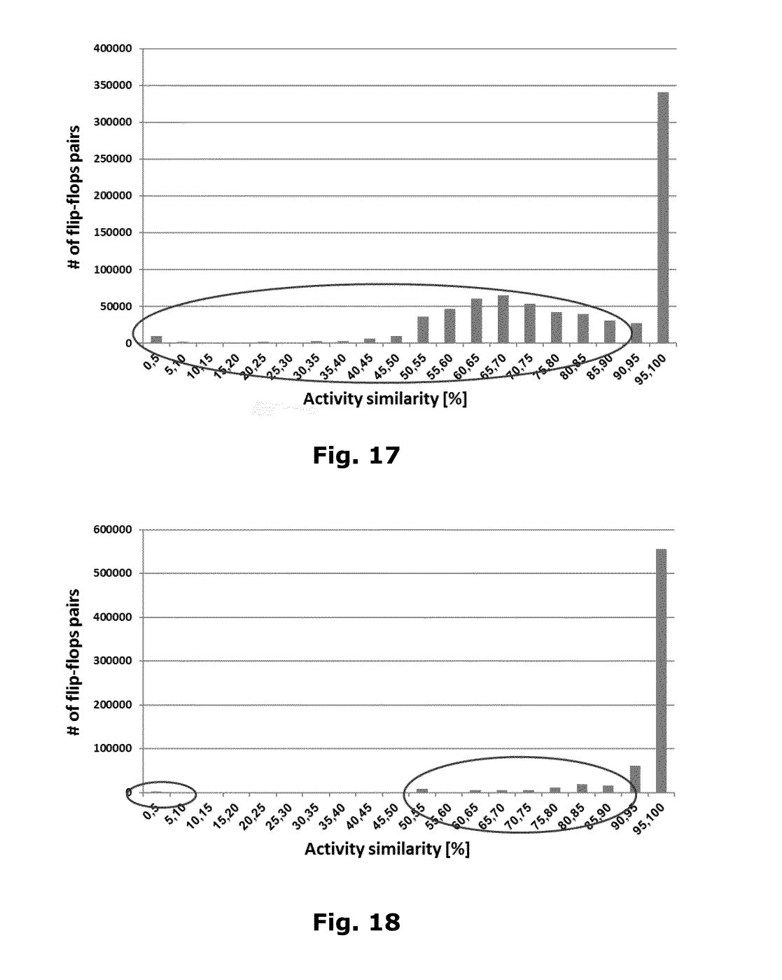

The graphs of FIG. 17 and FIG. 18 represent the activity similarities of the FFs in the systems described in FIG. 15 and FIG. 16, respectively. Only FFs in the same clock domain were paired. It is noted that different clock domains may have different duration m of enabled clock window. It was found that the activity similarity is very high, mostly due to the very low FFs' toggling during their enabled clock window. Nevertheless, it was surprisingly found that highly active and uncorrelated FFs pairs do exist is indicated by the encircled values on the graph. It is particularly noted that the FFs grouping algorithm should avoid putting the FFs of an encircled pair into the same group.

To model the switching power consumed when driving FFs pairs with a common gater (k=2), an n-vertex complete weighted graph G(V,E,w), known as the FF pairwise activity graph, is defined. Without loss of generality, it is assumed that n is even as otherwise a never toggling FF may artificially be added and the weight of its entire incident edges set to zero. A vertex vᵢεV is associated with FFᵢ's activity aᵢ. An edge eᵢⱼ=(v₁,vⱼ)εE is associated with a joint activity vector aᵢ|aⱼ, where the OR is a bit-wise operation. An edge eᵢⱼ is assigned a weight w(eᵢⱼ)=∥aᵢ⊕aᵢ∥, which counts the number of redundant clock pulses incurred by clocking FFᵢ and FFⱼ with a common gater. Let E′⊂3, |E′|=n/2, be a vertex matching of G (V,E,w). The total power P consumed by the clock signal depends on the number of clock pulses driving the FFs, and is given by

$$P = 2 {\sum }_{{e}_{ij} ∈ {E}^{′}} ‖ {a}_{i} \vert {a}_{j} ‖ = {\sum }_{{v}_{i} ∈ V} ‖ {a}_{i} ‖ + {\sum }_{{e}_{ij} ∈ {E}^{′}} [ ‖ {a}_{i} ⊕ ( {a}_{i} \vert {a}_{j} ) ‖ + ‖ {a}_{j} ⊕ ( {a}_{i} \vert {a}_{j} ) ‖ ] = {\sum }_{{v}_{i} ∈ V} ‖ {a}_{i} ‖ + {\sum }_{{e}_{ij} ∈ {E}^{′}} ‖ {a}_{i} ⊕ {a}_{j} ‖ = {\sum }_{{v}_{i} ∈ V} ‖ {a}_{i} ‖ + {\sum }_{{e}_{ij} ∈ {E}^{′}} w ( {e}_{ij} ) . \qquad ( 13 )$$

The first sum in the right hand side of (13) is the contribution due to the toggling of the individual FFs and is independent of the pairing. Therefore, to consume minimum dynamic power (or alternatively, achieve maximum dynamic power savings) it is necessary to minimize Σₑ_{ᵥ}_{εE′}w(eᵥ), which turns into the well-known minimal cost perfect graph matching (MCPM) problem, for which polynomial complexity algorithms are known [17].

The extension for k>2 is straightforward. Assume without loss of generality that n is divisible by k as otherwise we could artificially add a few never toggling FFs. A complete k-uniform weighted hypergraph H(V,E,w), called FF grouping activity hypergraph, is defined, where for a subset v⊂V and |v|=k, eᵥ={vᵤ}_{uεv}εE defines a hyper edge. It follows that

$$\vert E \vert = ( \begin{matrix}n \\ k\end{matrix} ) .$$

A hyper edge eᵥ is associated with a joint activity vector ∪_{uεv}aᵤ, defined by the bit-wise ORing of the k toggling vectors. A hyper edge eᵥ is assigned a weight

$$w ( {e}_{v} ) = {\sum }_{v ∈ v} ‖ {a}_{v} ⊕ {⋃}_{u ∈ v} {a}_{u} ‖ , \qquad ( 14 )$$

which is the total number of redundant clock pulses incurred by clocking the k FFs corresponding to eᵥ with a common gater.

Let E′⊂E be an exact cover of the vertices of H(V,E,w) by n/k hyper edges (a vertex belongs to one and only one hyper edge). The total power P consumed by the clock signal depends on the total number of pulses driving the FFs, given by

$$P = {\sum }_{{e}_{v} ∈ {E}^{′}} k ‖ {⋃}_{u ∈ v} {a}_{u} ‖ = {\sum }_{{v}_{i} ∈ V} ‖ {a}_{i} ‖ + {\sum }_{{e}_{v} ∈ {E}^{′}} {\sum }_{v ∈ v} ‖ {a}_{v} ⊕ {⋃}_{u ∈ v} {a}_{u} ‖ = {\sum }_{{v}_{i} ∈ V} ‖ {a}_{i} ‖ + {\sum }_{{e}_{v} ∈ {E}^{′}} w ( {e}_{v} ) . \qquad ( 15 )$$

The first sum in the right hand side of (15) is the contribution due to the toggling of the individual FFs and is independent of the grouping. Therefore, to consume minimum dynamic power or to achieve maximum dynamic power savings it may be necessary to minimize Σₑ_{ᵥ}_{εE′}w(eᵥ), a problem termed MIN_CLK_GATE. A solution to the problem of finding n/k hyper edges exactly covering the n vertices and yielding minimum redundant clock pulses may be derived from a solution to the NP-hard weighted Set Partitioning Problem (SPP) or the like, where hyper edges are the variables covering the vertex constraints.

A bottom-up process is proposed to solve the grouping problem involving the repeating of the MCPM algorithm. Starting with the n individual FFs and constructing the associated n-vertex FF pairwise activity graph, an MCPM algorithm then finds the best FFs pairing. A new n/2-vertex pairwise activity graph is then defined where its vertices correspond to the matching (n/2 edges) found in the former step. The process repeats K times until groups of size k=2^{K} are determined.

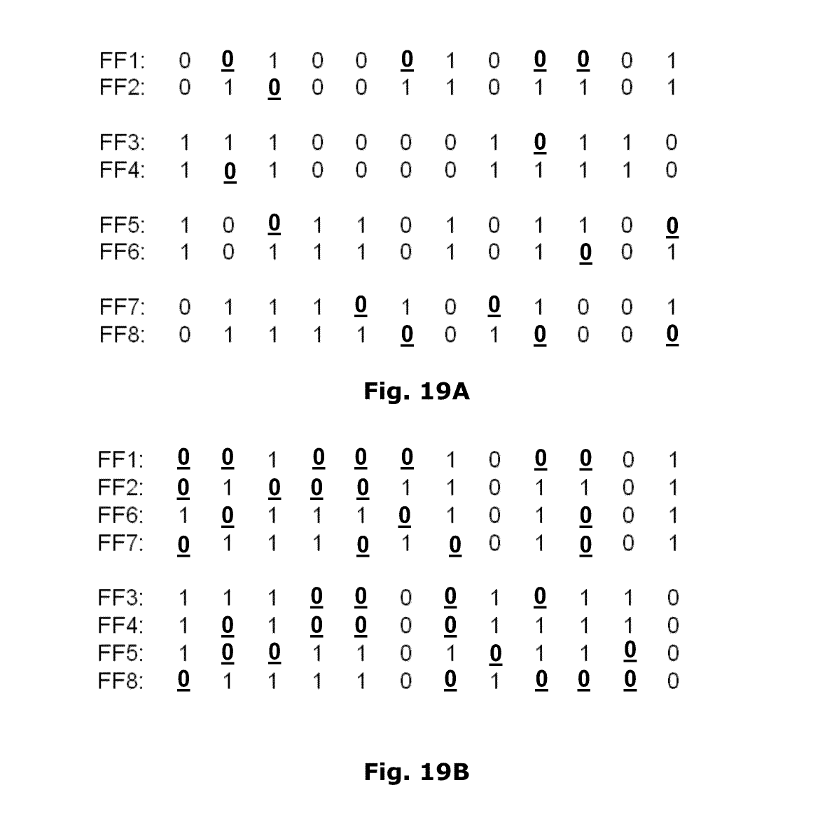

For k=2 (K=1) MCPM may solve the problem of minimizing the number of redundant clock pulses. Nevertheless it has been surprisingly found that the repetitive application of MCPM for k>2 (K>1) may not result in the minimum number of redundant clock pulses. This is demonstrated by the counterexample illustrated in FIGS. 19A and 19B, where k=4 (K=2). The toggling vectors of eight FFs are shown in FIG. 19A. Applying MCPM yields the pairs (FF₁,FF₂), (FF₃,FF₄), (FF₅,FF₆) and (FF₇,FF₈) with ∥a₁⊕a₂∥+∥a₃⊕a₄∥+∥a₅⊕a₆∥+∥a₇⊕a₈∥=15 redundant clock pulses (underlined). This is indeed the optimal pairing of FFs (2-size sets). However, the optimal 4-size grouping is (FF₁,FF₂,FF₆,FF₇) and (FF₃,FF₄,FF₅,FF₈), yielding 35 redundant clock pulses. The pairs (FF₅,FF₆) and (FF₇,FF₈) have been split between the two 4-size sets shown in FIG. 19B. Consequently, the optimal solution could not be obtained by a repetitive MCPM.

Nevertheless, it has been demonstrated that the MCPM algorithm is practical, yielding results close to the minimal cost SPP solution, as demonstrated by the following example. Since the number

$$( \begin{matrix}n \\ k\end{matrix} )$$

of SPP variables increases rapidly with the number n of FFs and the group size k, we could afford only a small design of n=94 FFs. The FF toggling benchmark spans m=10⁵ clock cycles and has a p=0.0736 average toggling. The case k=4 , yielding a minimum cost SPP with

$$( \begin{matrix}94 \\ 4\end{matrix} ) ≅ 3.05 \times {10}^{6}$$

variables and 94 constraints was compared. Though in reality only FFs that are in layout proximity with each other are allowed to belong to the same FF group as discussed herein, in this comparison any set of four FFs are allowed to participate in covering selection since the FFs of that experiment are anyway close to each other in the layout. The absolute minimum obtained by minimum cost SPP algorithm has Σₑ_{ᵥ}_{εE′}w(eᵥ)=578,671 redundant pulses, while the MCPM algorithm yielded 604,545 redundant pulses, which is 4.47% extra toggling compared to the optimal solution.

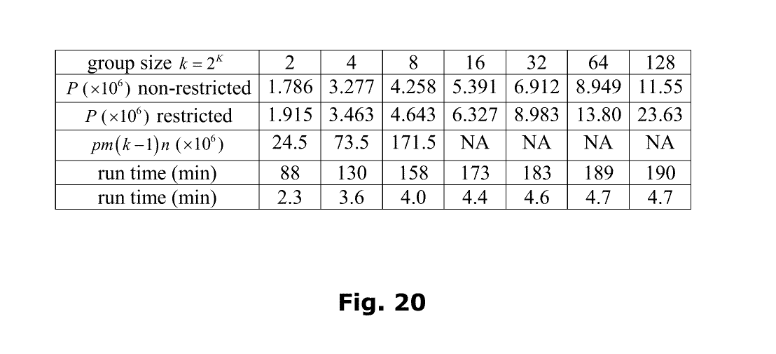

Furthermore, the MCPM algorithm may have reasonable run time performance as illustrated in the rows labeled ‘non-restricted’ in the table of FIG. 20, which is derived for the 3D graphics accelerator design used in the analysis hereinabove, comprising n=4.9×10³FFs. The toggling benchmark spans m=10⁵ clock cycles and has p=0.05 average FF toggling. The example ran on a 2GHz processor with 2 gigabyte RAM. Since all FFs pairs are allowed the pairwise activity graph includes 4.9×10³ vertices and n(n−1)/2=1.2×10⁷ edges. Due to FFs placement and proximity constraints the size of such a graph in practice is much smaller as will be explained subsequently in Section 4. Groups of k=2^{K}=2,4,8, . . . ,128 have been examined.

The number of redundant clock pulses is far smaller than that obtained for the worst case where FFs' togglings are disjointed from each other, yielding for small p and small k the P=pm(k−1)n redundant pulses. It is noted that the Not Applicable (NA) entries in the table of FIG. 20 follow from the invalidity of the expression for large k. The low number of redundant pulses obtained in the experiment stems from the correlations of FFs activities which the grouping algorithm may have exploited. The run-time growth is nearly logarithmic in K. This follows from the iterative nature of group constructions where at each step a problem of size half of the former iteration is solved.

### Physical Layout

In addition to finding sets of FFs to minimize the number of redundant clock pulses to maximize power savings, it may be necessary to consider the physical layout of the FFs. The physical aspect of FF layout involves the on-die locations of FFs and gaters, and may direct affect the power consumption due to the routing required for their connection, and hence their capacitive load. It is particularly noted that the physical location of FFs affects the delay and clock skew, and it may therefore be desirable for FFs driven jointly by the same clock gater, to be placed in proximity of each other.

A scheme for constructing clock trees when the positions of the FFs in leaves may involve minimizing a cost function weighting the sum of clock activities and clock pin distances. Such a cost function may be problematic since the physical meaning of a weighted sum of activities and distances is not well defined and requires delicate tuning of the weights. Furthermore, it is possible to generate a counterexample where the weighted pairing heuristic yields the worst solution. Another method may be to sum the products of activity by the distance of the FFs sets. It is noted that the sum of products has the physical units of effective capacitance, thus explicitly measuring power consumption, and no weights are needed.

To support activity-distance products the FF grouping activity hypergraph H(V,E,w) defined hereinabove may be modified in order to account for the FFs layout proximity. It is assumed that some knowledge of the preferred FFs locations in the layout is available. This can, for instance, be obtained by running first a placement of the nominal design without the data-driven clock gating circuits. It is supposed to place FFs close to the logic where they are being used, and also place closely FFs belonging to the same clock domain. Based on this data, the weight w(eᵥ) of a hyper edge in (14) which considered only the number of redundant clock pulses, may be modified as follows:

$$w ( {e}_{v} ) = d ( v ) {\sum }_{v ∈ v} ‖ {a}_{v} ⊕ {⋃}_{u ∈ v} {a}_{u} ‖ , \qquad ( 16 )$$

where d (v) is the diameter of the smallest circle enclosing the v's FFs. Substituting (16) in (15), the problem of maximizing the power savings turns into finding a subset E′⊂E of n1 k hyper edges exactly covering the vertices of H(V,E,w) so as to minimize the expression:

$${\sum }_{{e}_{v} ∈ {E}^{′}} w ( {e}_{v} ) = {\sum }_{{e}_{v} ∈ {E}^{′}} d ( v ) {\sum }_{v ∈ v} ‖ {a}_{v} ⊕ {⋃}_{u ∈ v} {a}_{u} ‖ \qquad ( 17 )$$

Any algorithm for solving SPP may be adequate to solve the MIN CLK GATE problem. Although SPP is NP-hard, and hence its corresponding algorithms may have limited capability, the number n of FFs in a clock domain (vertices of H) is limited.

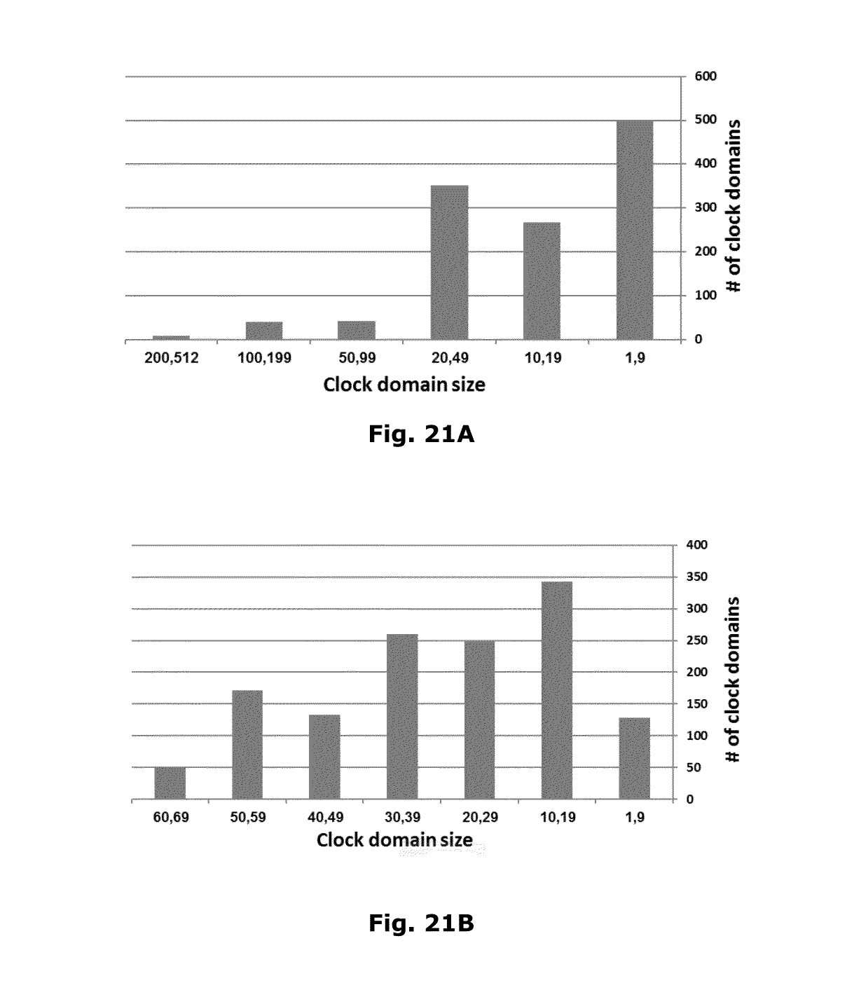

Referring to the graphs of FIGS. 21A and 21B, showing the distribution of the number of FFs in a clock domain of a DSP block and a network processor control block respectively. The distribution of the number of FFs in a clock domain is illustrated for the examples represented in FIGS. 15 and 16, respectively. As shown hereinabove in relation to FIG. 9, the typical size of k falls between 3 and 8, so solving SPP with

$$( \begin{matrix}n \\ k\end{matrix} )$$

variables (hyper edges of H, FF sets) and n constraints (vertices of H , FFs) is feasible. Moreover, imposing a constraint d(v)≦D on the diameter of the smallest circle enclosing the FFs (vertices) in a FF set (hyper edge), where D bounds the allowable diameter, further contracts H(V,E,w). The resulting SPPs can then be solved for each clock domain by the CPLEX solver.

The exact partition of the FFs of a clock domain into n/k k-size sets is not always possible in practice, either because n is not divisible by k or because the proximity constraints d(v)≦D may not always be satisfied. Moreover, the derivation of the optimal k in equation (11) is based on the average FFs toggling probabilities. In some cases it may be known that the toggling of some FFs is highly correlated and their joint clocking by a common gater is favorable, even if their number exceeds k. A practical design flow should support such exceptions by allowing the user to initially group FFs manually and leave the rest FFs for automatic grouping.

The grouping experiment for the 3D graphics accelerator may be rerun with restriction to clock domain and FF proximity constraints of 50 microns. The results are summarized in the rows labeled ‘restricted’ in the table of FIG. 20. As can be seen, the number of redundant clock pulses has been slightly increased compared to the non-restricted case, but this is compensated by a smaller routing overhead of connecting FFs and a gater of a group. It is noted that the run time is very small compared to the non-restricted case since the constraints imposed by the clock domains and physical position proximity significantly dilute the edges in the corresponding pairwise activity graph.

### Implementation and Integration

A possible implementation of data-driven clock gating is presented below as a part of a standard backend design flow. It consists of the following actions:
Studying the FFs toggling probabilities. This may involve, for example, running an extensive test bench representing typical operation modes of the system to determine the size k of a gated FF group based on a formula such as equation (11) or the like.
Running a placement tool to get preliminary preferred locations of FFs in the layout.
Employing a FFs grouping tool to implement the model and algorithms presented hereinabove, using the toggling correlation data obtained from studying the toggling probabilities and FFs locations data obtained from the placement tool. The outcome of this step is k-size FF sets (with manual overrides if required), where the FFs in each set will be jointly clocked by a common gater. It is noted that optionally, the grouping may be executed independently or alternatively to running the placement tool.
Introducing the data-driven clock gating logic into the hardware description (for example using Verilog HDL or the like). This may be performed automatically by a software tool, adding appropriate statements to implement the logic. The FFs are connected according to the grouping obtained above. Where appropriate, the gating logic may be introduced into RTL or gate-level description or both as required.
Re-running the test bench to obtain new statistics in order to verify the full identity of FFs' outputs before and after the introduction of gating logic. Though data-driven gating by its very definition should not change the logic of signals, and hence FFs toggling should stay identical, a robust design flow may implement this step.
Ordinary backend flow completion.—From this point the backend design flow proceeds by applying ordinary place and route tools. This is followed by running clock-tree synthesis, where some adaptations of the tool are required to support the already defined FFs connections to gaters.

It is noted that the total delay constraints of the feedback loop in FIG. 3 must not exceed the delay margins of paths from the clock input clk_g of FF₁ to the data input D₂ of FF₂. Most of the delay margins may be large enough to absorb the introduction of the gating logic. If at a later stage timing violations due to the gating are found, one may drop the data-driven gating from the troublesome FFs. In simulations less than 5% of the FFs were found. Relaxation of the clock cycle may also overcome this problem but it may be considered in a wider context of power-delay tradeoff and product specifications.

The above design flow was tested on the 3D graphics accelerator example described hereinabove. A full data-driven clock gating was implemented. It has been found that for p=0.05 average FF toggling the group size maximizing the net power savings is k=4. The power savings were measured and compared between the nominal and gated designs using a power simulator. The measurements accounted for the logic overhead required for the gating, thus measurements reflect the net savings. The dynamic power savings was 15%. This presents a total of 10% power reduction including static leakage power in our 65 nanometer backend implementation.

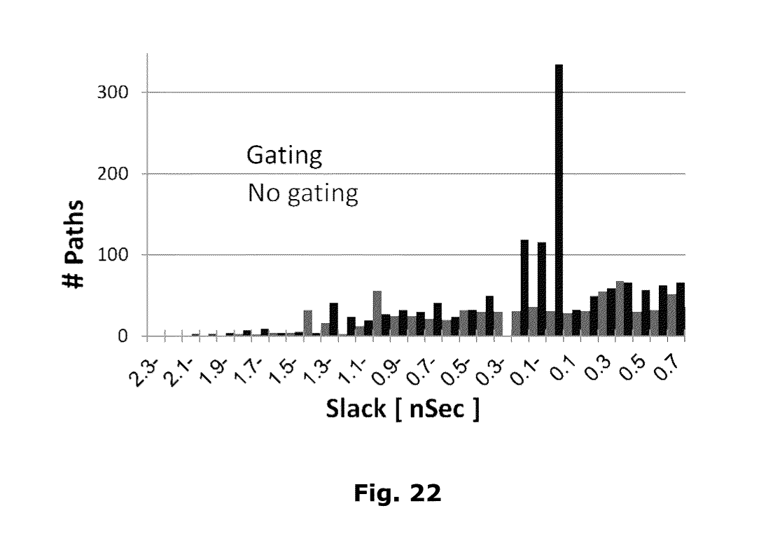

The gating scheme has considerable timing implications as indicated hereinabove. To quantify the timing impact of data-driven clock gating, static timing analysis may be executed on the native design without gating and then compared to the design comprising gating. The graph of FIG. 22 illustrates the margin (slack) distribution for 200 MHz clock cycle. It is shown that the margin distribution was slightly worsened as can be observed from the extra paths appearing on the negative side of the slacks.

Accordingly, the problem has been considered of how to group FFs for joint clocking by a common gater to yield maximal dynamic power savings. A related combinatorial problem called MIN_CLK_GATE was formulated and shown to be NP-hard. Though a difficult problem, a few practical algorithms to solve it are disclosed which may be particularly useful in a real design automation implementation. The solution was integrated in a practical design flow. Experimental results of a 65 nanometer 200 MHz 3D graphics accelerator were presented, 10% of net power reduction with no degradation of the clock cycle.

Although the disclosure herein is directed to the FFs residing at the leaves of the clock-tree, it is noted that the grouping algorithms with appropriate modifications may be applicable for construction of higher levels of the clock-tree, up to its root, while preserving the clock domains constraints imposed at the system level. In particular, the FF grouping problem may further arise in multi-bit FF (MBFF), where distinct FFs are combined in one physical cell to share their internal clock drivers. Thus the combination of data-driven gating with MBFF may yield further power savings.

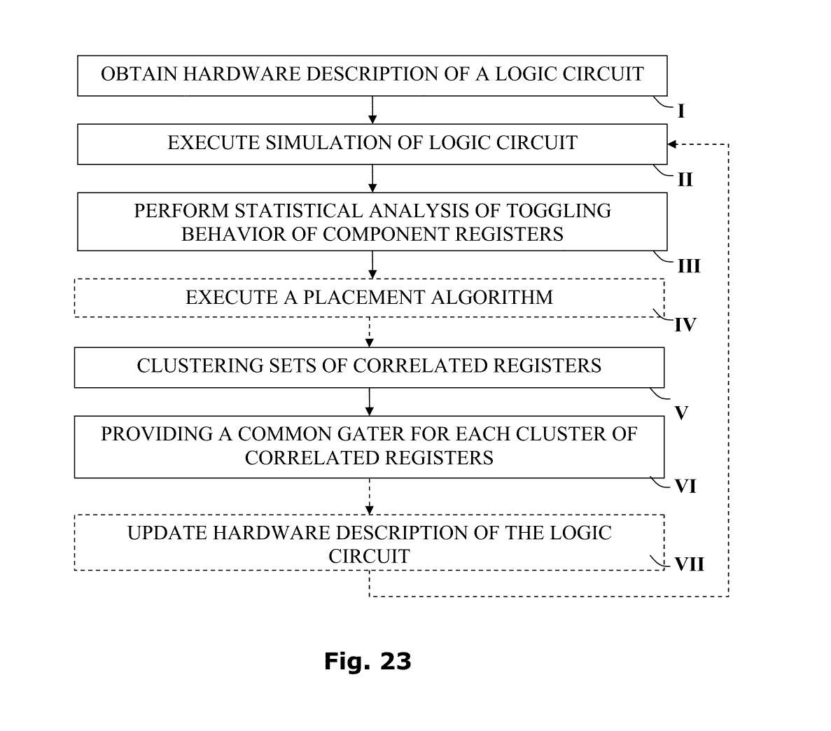

Referring now to the flowchart of FIG. 23 a selection of activities are presented of a method for generating a gating network for a Very Large Scale Integration (VLSI) circuit. The method includes obtaining a hardware description of the logic circuit or system—I, executing a simulation of the logic circuit or system—II, performing statistical analysis of toggling behavior of component registers of the logic circuit or system—III, clustering sets of correlated registers—V and providing common clock gater for each cluster of correlated registers—VI.

As described hereinabove, optionally, an additional action may be introduced before the clustering of executing a placement algorithm—IV. Accordingly, registers may be clustered which may be situated in a similar vicinity.

Where required, the hardware may be updated to include the clock gaters—VII and the process repeated to add higher level gating as appropriate. It will be appreciated that such a method may allow the gating network to be generated independently from the logical structure of the circuit.

Technical and scientific terms used herein should have the same meaning as commonly understood by one of ordinary skill in the art to which the disclosure pertains. Nevertheless, it is expected that during the life of a patent maturing from this application many relevant systems and methods will be developed. Accordingly, the scope of the terms such as computing unit, network, display, memory, server and the like are intended to include all such new technologies a priori.

As used herein the term “about” refers to at least ±10%.

The terms “comprises”, “comprising”, “includes”, “including”, “having” and their conjugates mean “including but not limited to” and indicate that the components listed are included, but not generally to the exclusion of other components. Such terms encompass the terms “consisting of” and “consisting essentially of”.

The phrase “consisting essentially of” means that the composition or method may include additional ingredients and/or steps, but only if the additional ingredients and/or steps do not materially alter the basic and novel characteristics of the claimed composition or method.

As used herein, the singular form “a”, “an” and “the” may include plural references unless the context clearly dictates otherwise. For example, the term “a compound” or “at least one compound” may include a plurality of compounds, including mixtures thereof.

The word “exemplary” is used herein to mean “serving as an example, instance or illustration”. Any embodiment described as “exemplary” is not necessarily to be construed as preferred or advantageous over other embodiments or to exclude the incorporation of features from other embodiments.

The word “optionally” is used herein to mean “is provided in some embodiments and not provided in other embodiments”. Any particular embodiment of the disclosure may include a plurality of “optional” features unless such features conflict.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween. It should be understood, therefore, that the description in range format is merely for convenience and brevity and should not be construed as an inflexible limitation on the scope of the disclosure. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6 as well as non-integral intermediate values. This applies regardless of the breadth of the range.

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable subcombination or as suitable in any other described embodiment of the disclosure. Certain features described in the context of various embodiments are not to be considered essential features of those embodiments, unless the embodiment is inoperative without those elements.

Although the disclosure has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present disclosure. To the extent that section headings are used, they should not be construed as necessarily limiting.

The scope of the disclosed subject matter is defined by the appended claims and includes both combinations and sub combinations of the various features described hereinabove as well as variations and modifications thereof, which would occur to persons skilled in the art upon reading the foregoing description.

What is claimed is:

1. A method for generating a clock gating network for a Very Large Scale Integration (VLSI) system, said method comprising:
obtaining toggling probabilities of a plurality of flip-flops of the system;
clustering sets of correlated flip-flops having correlated toggling behavior; and
providing a common gater for each cluster of correlated flip-flops.

2. The method of claim 1 wherein said obtaining toggling probabilities comprises:
obtaining a hardware description of a logic system;
executing a simulation with a representative test bench of the logic system; and
performing statistical analysis of toggling behavior of the plurality of flip-flops.

3. The method of claim 1 wherein said clustering comprises:
determining a size k for each cluster; and
selecting k flip-flops having correlated toggling behavior.

4. The method of claim 1 further obtaining a preliminary layout of said flip flops by executing a placement algorithm, wherein said clustering comprises:
selecting a set of correlated flip-flops from a common vicinity.

5. The method of claim 1 further comprising generating an updated hardware description by introducing said common gaters into the hardware description of said circuit.

6. The method of claim 5 further comprising:
verifying flip-flop outputs for said updated hardware description.

7. The method of claim 1 further comprising:
applying place and route tools; and
executing clock-tree synthesis.

8. The method of claim 1 further comprising:
executing a gate-level simulation of the logic system including said clusters of correlated flip-flops and said gaters;
performing statistical analysis of the behavior of said gaters;
clustering sets of correlated gaters; and
providing a common higher level gater for each cluster of correlated low level gaters.

9. A method for generating a clock gating network for a logic system comprising a plurality of registers, said method comprising:
obtaining a hardware description of the logic system;
executing a simulation with a representative test bench of the logic system;
performing statistical analysis of behavior of the plurality of registers;
clustering sets of statistically correlated registers; and
providing a common gater for each cluster of correlated registers.

10. A clock gating network for a Very Large Scale Integration (VLSI) circuit, said network comprising a plurality of clusters of correlated registers said correlated registers having statistically correlated toggling behavior, wherein each cluster of correlated registers is gated by a common gater.

11. The clock gating network of claim 9 wherein said correlated registers are selected by obtaining a hardware description of a logic system, executing a gate-level simulation with a representative test bench of the logic system; and performing statistical analysis of toggling behavior of the plurality of registers.

12. The clock gating network of claim 9 further comprising a tree structure wherein at least one higher level gater is configured to drive a cluster of lower level gaters.

13. The clock gating network of claim 12 wherein at least one of the size k of each cluster of registers, the number α′ of gating levels and the number n of wires in the circuit are selected such that the power savings are maximized.

14. The clock gating network of claim 12 wherein the size k of each cluster of registers, the number α′ of gating levels and the number n of wires in the circuit are selected such that
$$\frac{d}{d k} {C}_{net saving}^{1 - {α}^{′}} = 0 ,$$
where C_{net saving}^{1-α′}=ncₙₑₜ_{_{—}}_{saving}¹+Σⱼ₌₂^{α′}(n/k^{j-1})cₙₑₜ_{_{—}}_{saving}^{j}.

15. The clock gating network of claim 9 wherein said correlated registers comprise flip-flops.

16. The clock gating network of claim 9 wherein said correlated registers comprise gated clusters of flip-flops.
